(19) United States
(12) Patent Application Publication
(10) Pub. No.: US 2026/0114169 A1
(43) Pub. Date: Apr. 23, 2026

(54) DISPLAY DEVICE

(71) Applicant: LG Display Co., Ltd., Seoul (KR)

(72) Inventors: Seongyong UHM, Paju-si (KR); Junggi KIM, Paju-si (KR); Dohyung KIM, Paju-si (KR); Jinsuk LEE, Paju-si (KR); Jihyeop KIM, Paju-si (KR); Kyunghee KIM, Paju-si (KR); Hyunsik KIM, Paju-si (KR)

(73) Assignee: LG Display Co., Ltd., Seoul (KR)

(21) Appl. No.: 19/314,302

(22) Filed: Aug. 29, 2025

(30) Foreign Application Priority Data
Oct. 18, 2024 (KR) 10-2024-0143204

(51) Int. Cl. H10K 59/80; H10K 59/122; H10K 59/40; H10K 59/65; H10K 77/10; H10K 102/00

(52) U.S. Cl. CPC H10K 59/8792; H10K 59/122; H10K 59/40; H10K 59/65; H10K 77/111; H10K 2102/351

(57) ABSTRACT

A display device according to an embodiment includes a substrate including a display area having a plurality of sub-pixels and a non-display area surrounding the display area, a first electrode disposed on the substrate for each of the sub-pixels, a bank disposed on the first electrode and overlapping a peripheral edge of an upper surface of the first electrode, an organic layer on the first electrode and the bank, a second electrode on the organic layer, a black matrix disposed at a boundary between adjacent sub-pixels on the second electrode, and a color filter on the second electrode and the black matrix, wherein the bank or the black matrix includes a multilayer thin film structure formed by alternating a plurality of high refractive index layers and a plurality of low refractive index layers.

### CROSS REFERENCE TO RELATED APPLICATION

The present application claims priority to Korean Patent Application No. 10-2024-0143204, filed Oct. 18, 2024, the entire contents of which is incorporated herein for all purposes by this reference.

### BACKGROUND

### Technical Field

This specification relates to a display device.

### Description of the Related Art

With the advancement of the information society, there is an increasing demand for display devices that can show images, and various types of display devices such as liquid crystal display (LCD) devices and organic light emitting diode (OLED) displays are being utilized.

The display device includes a plurality of pixels and is equipped with a plurality of switching elements to drive and control the pixels.

### BRIEF SUMMARY

The specification describes a polarizer-less flexible OLED display architecture optimized for foldable products. Flexibility and reduced thickness are achieved by omitting the polarizing unit and instead controlling external light reflection through a black matrix or bank composed of alternating high-and low-refractive-index layers. This multilayer thin-film structure suppresses red, green, and blue reflections via destructive interference while transmitting near-infrared light, enabling under-display optical devices such as cameras and sensors to operate without visible apertures.

Optical and mechanical performance are further enhanced through coordinated positioning and material selection of the bank and black matrix. The black matrix edge is recessed relative to the bank edge to increase viewing angle and brightness uniformity, while the bank itself contains black pigments to absorb incident light and prevent “halo” artifacts. Sub-pixel light-emitting layers are fabricated with color-specific thicknesses (R>G>B), and alternative multi-stack EML configurations share common transport/blocking layers while varying emissive layer thickness per color. Touch electrodes are integrated in non-emissive regions directly beneath the black matrix, concealing them from view while maintaining touch sensitivity.

The device also incorporates a mechanically engineered bending region for foldable operation. Inorganic panel layers are selectively removed in this area to expose the plastic substrate, improving bendability, while multi-layer dams and encapsulation structures protect surrounding circuitry and maintain environmental sealing. Designated optical areas within the display allow light transmission to underlying optoelectronic devices, with customizable shapes and arrangements to accommodate multiple components without degrading display quality.

Various embodiments of this specification provide a display device capable of enhancing applicability to foldable products by improving flexibility through the omission of a polarizing unit.

Various embodiments of this specification provide a display device capable of improving external light reflection (surface reflection) by adopting a black matrix or bank composed of a plurality of high-refractive-index layers and a plurality of low-refractive-index layers alternately stacked.

Various embodiments of this specification provide a display device incorporating a multilayer thin film structure capable of transmitting near-infrared light while causing destructive interference of red light, green light, and blue light.

Various embodiments of this specification provide a low-reflection display device capable of improving surface reflection of external light and operating with low power consumption.

The technical benefits of this specification are not limited to those mentioned above, and other technical benefits may be inferred from the following embodiments.

In order to accomplish the above benefits, a display device according to an embodiment includes a substrate including a display area having a plurality of sub-pixels and a non-display area surrounding the display area, a first electrode disposed on the substrate for each of the sub-pixels, a bank disposed on the first electrode and overlapping a peripheral edge of an upper surface of the first electrode, an organic layer on the first electrode and the bank, a second electrode on the organic layer, a black matrix disposed at a boundary between adjacent sub-pixels on the second electrode, and a color filter on the second electrode and the black matrix, wherein the bank or the black matrix includes a multilayer thin film structure formed by alternating a plurality of high refractive index layers and a plurality of low refractive index layers.

The specific details of other embodiments are included in the detailed description and drawings.

### BRIEF DESCRIPTION OF THE SEVERAL VIEWS OF THE DRAWINGS

FIG. 1 is a plan view of a display device according to an embodiment;

FIG. 2 is a cross-sectional view of the display panel of FIG. 1 in a bent state;

FIG. 3 is a cross-sectional view taken along line A-A′ of FIG. 1;

FIG. 4 is a detailed cross-sectional view of the lighting-emitting layer of FIG. 3;

FIG. 5 is a detailed cross-sectional view of the light-emitting layer according to an alternative embodiment;

FIG. 6 is a cross-sectional view of the touch layer of FIG. 3;

FIG. 7 is a cross-sectional view taken along line B-B′ of FIG. 1;

FIG. 8 is a cross-sectional view taken along line C-C′ of FIG. 1;

FIGS. 9 to 12 are schematic plan views of a display device according to an embodiment;

FIG. 13 is a diagram illustrating the arrangement of sub-pixels in the display area of a display panel according to an embodiment;

FIG. 14 is an enlarged cross-sectional view of the Q1 area of FIG. 3;

FIG. 15 is an enlarged cross-sectional view of the first black matrix of FIG. 14;

FIG. 16 is a graph illustrating the transmittance of near-infrared light with respect to wavelength in a black matrix according to an embodiment;

FIG. 17 is a cross-sectional view of a display device according to another embodiment;

FIG. 18 is a cross-sectional view of a display device according to another embodiment;

FIG. 19 is a cross-sectional view of a display device according to another embodiment;

FIG. 20 is a perspective view of a display device according to another embodiment; and

FIG. 21 is a cross-sectional view taken along line D-D′ of FIG. 20.

### DETAILED DESCRIPTION

Hereinafter, embodiments will be described with reference to accompanying drawings.

The same reference numerals refer to the same components.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In the specification, when a component (or area, layer, part, etc.) is mentioned as being “on top of,” “connected to,” or “coupled to” another component, it means that it may be directly connected/coupled to the other component, or a third component may be placed between them.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The expression “and/or” is taken to include one or more combinations that can be defined by associated components.

The terms “first,” “second,” etc., are used to describe various components, but the components should not be limited by these terms. The terms are used only for distinguishing one component from another component. For example, a first component may be referred to as a second component and, similarly, the second component may be referred to as the first component, without departing from the scope of the present disclosure. The singular forms are intended to include the plural forms as well unless the context clearly indicates otherwise.

The terms such as “below,” “lower,” “above,” “upper,” etc., are used to describe the relationship of components depicted in the drawings. The terms are relative concepts and are described based on the direction indicated on the drawing. For example, unless explicitly stated with terms such as “directly” or “immediately,” one or more other components may be positioned between two described components. Spatially relative terms such as “below,” “beneath,” “lower,” “above,” and “upper” may be used to facilitate the description of the relationship between one component or element and another, as illustrated in the drawings. These spatially relative terms should be understood to include different orientations of a component during use or operation, in addition to the orientation shown in the drawings. For instance, if a component shown in the drawings is flipped, a component described as being “below” or “beneath” another component may then be positioned “above” that component. Accordingly, the term “below,” for example, may encompass both upward and downward directions.

As used herein, the phrase “at least one of A, B, and C” encompasses any of A, B, or C individually, as well as any combination of two or more of A, B, and C together. Thus, the phrase covers embodiments that include only A, only B, or only C, embodiments that include A and B together, A and C together, or B and C together, and embodiments that include A, B, and C together. Unless otherwise expressly stated, the phrase does not imply any order, priority, or exclusivity among the listed elements, and the elements may be present in any suitable form, structure, or combination consistent with the context. This similarly applies to “at least one of A, B, C, and D” and so forth.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

The various features of the embodiments of the disclosure can combined or assembled together, either partially or entirely, in a technically diverse manner, and each embodiment can be independently implemented or in conjunction with related embodiments.

Hereinafter, the display device according to embodiments of this specification will be described with reference to the accompanying drawings.

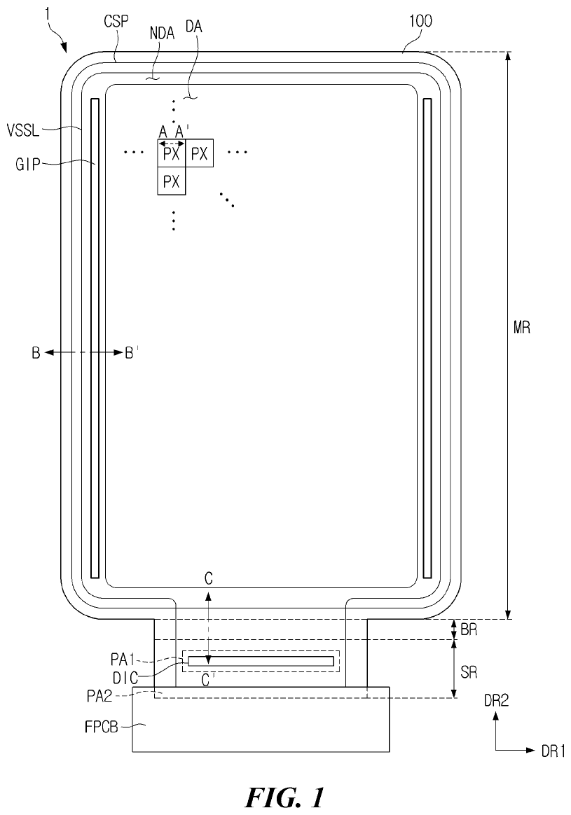

FIG. 1 is a plan view of a display device according to an embodiment;

Referring to FIG. 1, a display device 1 according to an embodiment may include a display panel 100. The display panel 100 may include a display area DA including a plurality of pixels PX and a non-display area NDA surrounding the display area DA. The display area DA may have a rectangular planar shape. However, the display area DA is not limited thereto and may have a square, circular, elliptical, or other polygonal planar shape. For example, the display area DA may have a rounded rectangular shape, but it is not limited thereto and may also be a rectangular shape with sharp corners.

In the embodiments, a first direction DR1 and a second direction DR2 are different directions that intersect each other, such as directions perpendicular to each other in a plan view. In FIG. 1, the first direction DR1 may correspond to the extending direction of the short sides of the display panel 100, while the second direction DR2 may correspond to the extending direction of the long sides of the display panel 100. However, it should be understood that the directions mentioned in the embodiments are relative and are not limited to the specific directions described.

The display area DA may include short sides extending along the first direction DR1 and long sides extending along the second direction DR2. The non-display area NDA may surround the display area DA. The non-display area NDA may be disposed on one side and the other side of the display area DA in the first direction DR1 and on one side and the other side of the display area DA in the second direction DR2.

A gate driving unit GIP may be arranged in the non-display area NDA located on each of one side and the other side of the display area DA in the first direction DR1. A low-potential voltage line VSSL may be disposed outside the gate driving unit GIP in the non-display area NDA. For example, as shown in FIG. 1, the low-potential voltage line VSSL may extend from a flexible printed circuit board FPCB, pass through a sub-region SR and a bending region BR, and be positioned outside the gate driving unit GIP in the non-display area NDA while surrounding the display area DA.

The non-display area NDA located on the opposite side of the display area DA in the second direction DR2 may extend further in the second direction DR2 from the central portion of that side of the display area DA. The width in the first direction DR1 of the non-display area NDA, which extends further in the second direction DR2 from the central portion of the opposite side of the display area DA in the second direction DR2, may be smaller than the width in the first direction DR1 of the non-display area NDA adjacent to the opposite side of the display area DA in the second direction DR2.

The display device 1 may include a main region MR, a sub-region SR, and a bending region BR between the main region MR and the sub-region SR. The display area DA and the non-display area NDA surrounding the display area DA on all four sides may form the main region MR, while the portion extending further in the second direction DR2 from the central portion of the other side of the display area DA may constitute the bending region BR and the sub-region SR. The bending region BR may be positioned between the sub-region SR and the main region MR. The sub-region SR may include a first pad area PA1 and a second pad area PA2 located at the opposite end of the sub-region SR in the second direction DR2. The display device 1 may further include a data driver DIC and a printed circuit board FPCB. The data driving unit DIC may be placed in the first pad area PA1, and the flexible printed circuit board FPCB may be attached to the second pad area PA2. The first pad area PA1 and the second pad area PA2 may each include a number of pads that connect the data driving unit DIC and the flexible printed circuit board FPCB. The data driving unit DIC may, for example, be provided in the form of a driving chip IC, but is not limited thereto. In an embodiment, the data driving unit DIC is arranged in a chip-on-plastic method, directly mounted on the display panel 100, but is not limited thereto, and may also be arranged in a chip-on-glass or chip-on-film method.

The display panel 100 according to an embodiment may further include a crack detection pattern CSP surrounding the low-potential voltage line VSSL. The crack detection pattern CSP may be arranged to completely surround the display area DA, as shown in FIG. 1. For example, the crack detection pattern CSP may be placed on the outer side of the low-potential voltage line VSSL. However, the embodiments of this specification are not limited thereto, and the crack detection pattern CSP may not be partially disposed in the non-display area NDA on the opposite side of the display area DA in the second direction DR2.

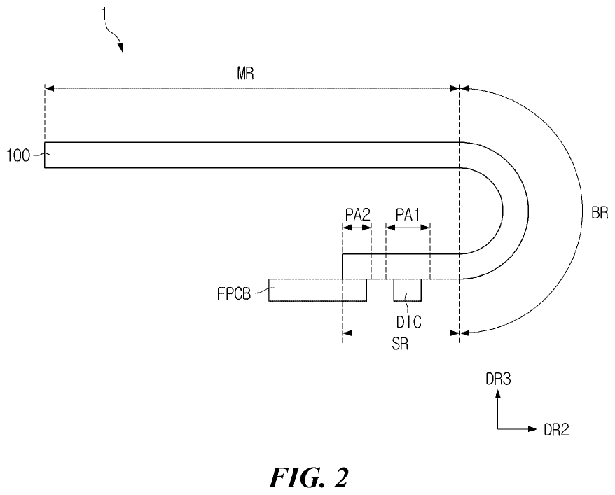

FIG. 2 is a cross-sectional view illustrating a bent state of the display panel in FIG. 1.

Referring to FIG. 2, the bending region BR of the display panel 100 of the display device 1 according to an embodiment may be bent in the thickness direction (or the third direction DR3). Through this, the main region MR and the sub-region SR may overlap in the thickness direction. The display panel 100 may be bent such that the bottom surface of the main region MR and the top surface of the sub-region SR face each other. A flexible printed circuit board FPCB may be attached to the end of the sub-region SR.

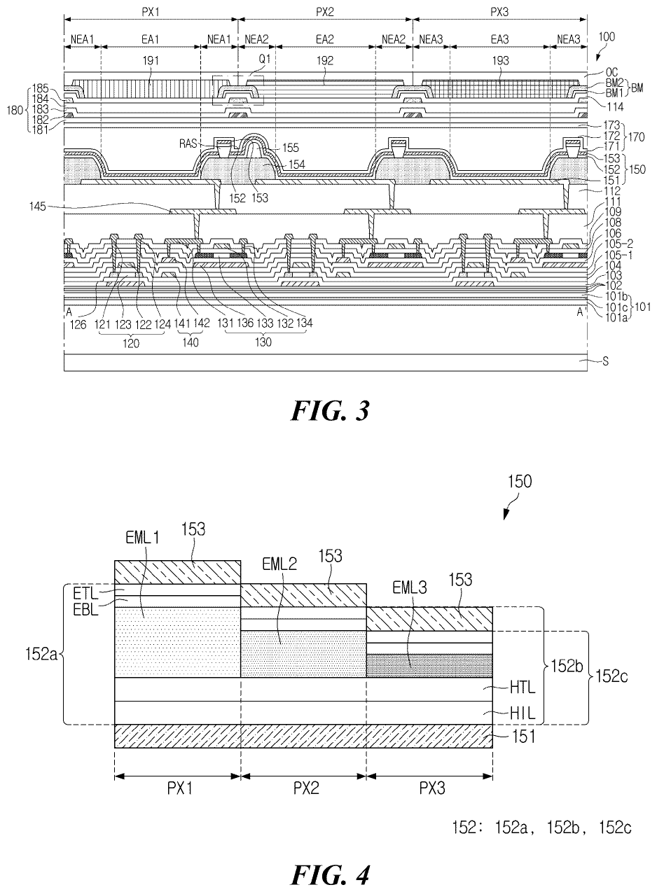

FIG. 3 is a cross-sectional view taken along line A-A′ of FIG. 1.

Referring to FIG. 3, the pixel PX (see FIG. 1) of the display panel 100 may include a plurality of sub-pixels PX1, PX2, and PX3. The first sub-pixel PX1 may be a red sub-pixel, the second sub-pixel PX2 may be a green sub-pixel, and the third sub-pixel PX3 may be a blue sub-pixel, but the embodiments of this specification are not limited thereto. In some embodiments, the pixel PX may further include a fourth sub-pixel, which may be a white sub-pixel, but the embodiments of this specification are not limited thereto. In some embodiments, the pixel PX may include one red sub-pixel, two green sub-pixels, and one blue sub-pixel, but the embodiments of this specification are not limited thereto. For example, a plurality of sub-pixels PX1, PX2, and PX3 may be arranged in a stripe arrangement along the first direction DR1, but are not limited thereto and may also be arranged in a pentile arrangement.

The display panel 100 may include a substrate 101, a first thin-film transistor 120, a second thin-film transistor 130, a light-emitting layer 150, an encapsulation layer 170, a touch layer 180, a filter insulating layer 114, a black matrix BM, color filters 191, 192, and 193, and a planarization layer OC. The display panel 100 may include at least one panel insulating layer between the substrate 101 and the light-emitting layer 150, and at least one touch insulating layer.

The at least one panel insulating layer may include at least one of a buffer layer 102, a first insulating layer 103, a second insulating layer 104, a third-1 insulating layer 105-1, a third-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

An optoelectronic device S may be disposed beneath the display panel 100. The optoelectronic device S may be disposed to overlap with the display area DA of the display panel 100.

The substrate 101 may include one or more plastic materials. For example, the substrate 101 may be a multi-substrate including a plurality of plastic materials, such as polyimide. For example, the substrate 101 may include a first substrate portion 101a and a second substrate portion 101b, each including a plastic material, and a third substrate portion 101c, which includes an inorganic insulating material between the first and second substrate portions 101a and 101b, but the embodiments of this specification are not limited thereto.

A buffer layer 102 may be disposed on the substrate 101. The buffer layer 102 may minimize or delay the diffusion of moisture or oxygen that penetrates into the substrate 101. The buffer layer 102 may be formed by alternately stacking silicon nitride (SiNx) and silicon oxide (SiOx) at least once, but the embodiments of this specification are not limited thereto.

A first light-shielding layer 126 may be disposed on the buffer layer 102. The first light-shielding layer 126 may prevent light from passing through the first semiconductor layer 123 of the first thin-film transistor 120. For example, the first semiconductor layer 123 may be arranged to overlap with the first light-shielding layer 126. The first light-shielding layer 126 may be a single layer or multiple layers made of molybdenum (Mo), aluminum (Al), chromium (Cr), nickel (Ni), neodymium (Nd), copper (Cu), or any of their alloys, but the embodiments of this specification are not limited thereto.

A first insulating layer 103 may be disposed on the buffer layer 102 and the first light-shielding layer 126. The first insulating layer 103 may prevent a short circuit between the components of the first thin-film transistor 120 and the first light-blocking layer 126. The first insulating layer 103 may be made of the same material as the buffer layer 102, but the embodiments of this specification are not limited thereto. For example, the first insulating layer 103 may be made of an inorganic insulating material, such as silicon nitride (SiNx) or silicon oxide (SiOx), but the embodiments of this specification are not limited thereto.

A first thin-film transistor 120 may be disposed on the first insulating layer 103. The first thin-film transistor 120 may include a first source electrode 121, a first gate electrode 122, a first semiconductor layer 123, and a first drain electrode 124.

The first semiconductor layer 123 may be disposed on the first insulating layer 103. The first semiconductor layer 123 may include a metal oxide semiconductor such as Indium-Gallium-Zinc Oxide (IGZO), or a silicon-based semiconductor material such as amorphous silicon or polycrystalline silicon, but the embodiments of this specification are not limited thereto. The first semiconductor layer 123 may include a channel region, a source region, and a drain region.

The polycrystalline semiconductor layer has higher mobility than the amorphous semiconductor layer and the oxide semiconductor layer, so it may have lower power consumption and improved reliability. Therefore, the driving transistor may be formed using a polycrystalline semiconductor layer.

A second insulating layer 104 may be disposed on the first semiconductor layer 123. The second insulating layer 104 may be made of the same material as the first insulating layer 103 and may prevent short circuits between the first semiconductor layer 123 and other components of the first thin-film transistor 120.

A first gate electrode 122 may be disposed on the second insulating layer 104. The first gate electrode 122 may be arranged to overlap with the channel region of the first semiconductor layer 123, positioned on the second insulating layer 104. The first gate electrode 122 may be composed of a single layer or multilayer structure that includes materials such as molybdenum (Mo), copper (Cu), titanium (Ti), aluminum (Al), chromium (Cr), gold (Au), nickel (Ni), neodymium (Nd), or their compounds, but the embodiments of this specification are not limited to these materials. The first gate electrode 122 may be arranged along with a gate line.

Third insulating layers 105-1 and 105-2 may be disposed on the first gate electrode 122. The third insulating layers 105-1 and 105-2 may be formed by alternating layers of silicon nitride (SiNx) and silicon oxide (SiOx) at least once, but the embodiments of this specification are not limited thereto. For example, the third-1 insulating layer 105-1 may include silicon oxide (SiOx), and the third-2 insulating layer 105-2 may include silicon nitride (SiNx), but the embodiments of this specification are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be made of a metal material. For example, the first source electrode 121 and the first drain electrode 124 may be composed of a single layer or multiple layers made of any one of molybdenum (Mo), aluminum (Al), chromium (Cr), gold (Au), titanium (Ti), nickel (Ni), neodymium (Nd), copper (Cu), or their alloys, but the embodiments of this specification are not limited thereto.

The first source electrode 121 and the first drain electrode 124 may be arranged along with the data line. For example, the data line may be formed in the same layer and made of the same material as the first source electrode 121 and the first drain electrode 124, but the embodiments of this specification are not limited thereto.

The storage electrode 140 may be disposed apart from the first thin-film transistor 120. The storage electrode 140 may include a first storage electrode 141 and a second storage electrode 142.

The first storage electrode 141 may be disposed in the same layer and made of the same material as the first gate electrode 122, but the embodiments of this specification are not limited thereto.

The second storage electrode 142 may be disposed on the first storage electrode 141. The second storage electrode 142 may be disposed on the third insulating layers 105-1 and 105-2, and a capacitance may be formed between the first storage electrode 141 and the second storage electrode 142 with the third insulating layers 105-1 and 105-2 acting as a dielectric. The second storage electrode 142 may be made of the same material as the first storage electrode 141, but the embodiments of this specification are not limited thereto.

The second thin-film transistor 130 may be disposed spaced apart from the first thin-film transistor 120 and the storage electrode 140. The second thin-film transistor 130 may include a second source electrode 131, a second gate electrode 132, a second semiconductor layer 133, and a second drain electrode 134.

A second light-shielding layer 136 may be disposed in the same layer as the second storage electrode 142.

The second light-blocking layer 136, similar to the first light-blocking layer 126, may prevent light from reaching the second semiconductor layer 133, thereby extending the lifespan of the second thin-film transistor 130. For example, the second semiconductor layer 133 may be arranged to overlap with the second light-blocking layer 136.

A fourth insulating layer 106 may be disposed on the second light-blocking layer 136. The fourth insulating layer 106 may be made of the same material as the first insulating layer 103, the second insulating layer 104, or the third insulating layer 105-1 and 105-2, but the embodiments of this specification are not limited thereto.

The second semiconductor layer 133 may be disposed on the fourth insulating layer 106. The second semiconductor layer 133 may include a source region, a drain region, and a channel region between the source and drain regions.

The second semiconductor layer 133 may include a semiconductor material such as a metal oxide semiconductor like Indium-Gallium-Zinc Oxide (IGZO), or a silicon-based semiconductor material such as amorphous silicon or polycrystalline silicon, but the embodiments of this specification are not limited thereto

The fifth insulating layer 108 may be disposed on the second semiconductor layer 133. The fifth insulating layer 108 may be made of the same material as the first insulating layer 103, the second insulating layer 104, the third insulating layer 105-1 and 105-2, or the fourth insulating layer 106, but the embodiments of this specification are not limited thereto

The second gate electrode 132 may be disposed on the fifth insulating layer 108.

The second gate electrode 132 may be made of the same material as the first gate electrode 122. For example, the second gate electrode 132 may be formed as a single layer or multiple layers made from materials such as molybdenum (Mo), copper (Cu), titanium (Ti), aluminum (Al), chromium (Cr), gold (Au), nickel (Ni), neodymium (Nd), or alloys of these materials, but the embodiments of this specification are not limited thereto

The sixth insulating layer 109 may be disposed on the second gate electrode 132. The sixth insulating layer 109 may be made of the same material as the first insulating layer 103, second insulating layer 104, third insulating layer 105-1 and 105-2, fourth insulating layer 106, or fifth insulating layer 108, but the embodiments of this specification are not limited thereto

The first source electrode 121, first drain electrode 124, second source electrode 131, and second drain electrode 134 may be disposed on the sixth insulating layer 109.

The second source electrode 131 and second drain electrode 134 may be made of the same material as the first source electrode 121 and first drain electrode 124 and may be disposed in the same layer, but the embodiments of this specification are not limited thereto. For example, the second source electrode 131 and second drain electrode 134 may be formed as a single layer or multiple layers made from materials such as molybdenum (Mo), aluminum (Al), chromium (Cr), gold (Au), titanium (Ti), nickel (Ni), neodymium (Nd), and copper (Cu) or alloys of these materials, but the embodiments of this specification are not limited thereto. For example, the second source electrode 131 may be electrically connected to the second storage electrode 142. The second source electrode 131 may be electrically connected to the second storage electrode 142 by passing through the sixth insulating layer 109, fifth insulating layer 108, and fourth insulating layer 106.

The first thin-film transistor 120 may be a driving transistor, and the second thin-film transistor 130 may be a switching transistor, but the embodiments of this specification are not limited thereto

The first source electrode 121 and the first drain electrode 124 may have a first protective layer 111 disposed thereon.

The first protective layer 111 may flatten the upper part of the first thin-film transistor 120 and protect the first thin-film transistor 120. The first protective layer 111 may be made of an organic material. For example, the first protective layer 111 may be made of an organic material such as acrylic resin, epoxy resin, phenolic resin, polyamide resin, or polyimide resin, but the embodiments of this specification are not limited thereto The second protective layer 112 may be disposed on the first protective layer 111.

The second protective layer 112 may be formed of the same material as the first protective layer 111, but the embodiments of this specification are not limited thereto

In some embodiments, a third protective layer may be further disposed on the upper surface of the second protective layer 113, but the embodiments of this specification are not limited thereto

A connection electrode 145 may be disposed between the first protective layer 111 and the second protective layer 112.

The connection electrode 145 may electrically connect the first thin-film transistor 120 and the light-emitting layer 150. The connection electrode 145 may be made of the same material as the first source electrode 121 and the first drain electrode 124, but the embodiments of this specification are not limited thereto

The connection electrode 145 may be a single layer or multilayer made of any one of molybdenum (Mo), aluminum (Al), chromium (Cr), gold (Au), titanium (Ti), nickel (Ni), neodymium (Nd), or copper (Cu), or alloys thereof, but the embodiments of this specification are not limited thereto.

The light-emitting layer 150 may be disposed on the second protective layer 112. The light-emitting layer 150 may include a first electrode 151, an organic layer 152, and a second electrode 153. The first electrode 151 may function as the anode, and the second electrode 153 may function as the cathode.

The first electrode 151 may be disposed on the second protective layer 112. The first electrode 151 may be electrically connected to the first thin-film transistor 120 through a contact hole formed in the second protective layer 112. The first electrode 151 may be a reflective electrode that reflects light, but the embodiments of this specification are not limited thereto. The first electrode 151 may include a laminated structure (Ti/Al/Ti) of aluminum (Al) and titanium (Ti), a laminated structure (ITO/Al/ITO) of aluminum (Al) and ITO, or a high-reflectivity metal material such as APC alloy, and may be formed as a single layer or multiple layers, but the embodiments of this specification are not limited thereto.

The organic layer 152 may be disposed on the first electrode 151. The organic layer 152 may include one or more light-emitting structures (or light-emitting elements or devices) stacked in either the order of hole transport layer and electron transport layer, or in the reverse order, on the first electrode 151. For example, the hole delivery layer may include a hole transport layer, hole injecting layer, electron blocking layer, or P-type charge generating layer, but the embodiments of this specification are not limited thereto. For example, the electron delivery layer may include an electron transport layer, electron injecting layer, hole blocking layer, or N-type charge generating layer, but the embodiments of this specification are not limited thereto. The organic layer 152 may be an organic light-emitting layer, an inorganic light-emitting layer, a quantum dot light-emitting layer, a micro light-emitting diode, or a micro-mini light-emitting diode, but the embodiments of this specification are not limited thereto. For example, the display panel 100 according an embodiment of this specification, the organic layer 152 may include an organic light-emitting layer. The organic layer 152 may include a red light-emitting layer, a green light-emitting layer, and a blue light-emitting layer. The organic layer 152 may further include a white light-emitting layer, but the embodiments of this specification are not limited thereto. Hereinafter, the detailed structure of the organic layer 152 according to an embodiment will be described.

FIG. 4 is a detailed cross-sectional view of the light-emitting layer of FIG. 3.

Referring to FIG. 4, the light-emitting layer 150 may extend across a first sub-pixel PX1, a second sub-pixel PX2, and a third sub-pixel PX3.

The thickness of the light-emitting layer 150 may differ in each sub-pixel PX1, PX2, and PX3, but the embodiments of this specification are not limited thereto, and the thickness of the light-emitting layer 150 in each sub-pixel PX1, PX2, and PX3 may also be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. The light-emitting layers EML1, EML2, and EML3 in the respective organic layers 152a, 152b, and 152c may be physically separated, but the lower and upper layers of the light-emitting layers EML1, EML2, and EML3 may be integrally formed across the sub-pixels PX1, PX2, and PX3. The light-emitting layers EML1, EML2, and EML3 may differ in thickness. For example, the thickness of the first light-emitting layer EML1 may be the largest, followed by the second light-emitting layer EML2, and the thickness of the third light-emitting layer EML3 may be the smallest, but the embodiments of this specification are not limited thereto.

The hole injection layer HIL may be disposed on the first electrode 151. The hole injection layer HIL may be positioned between the first electrode 151 and the light-emitting layers EML1, EML2, and EML3. The hole injection layer HIL may be integrally formed across the sub-pixels PX1, PX2, and PX3. For example, the hole injection layer HIL may be made of a hole injection material selected from substances such as MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazole-3-yl)phenyl)-9H-fluorene-2-amine, but the embodiments of this specification are not limited thereto.

The hole transport layer HTL may be disposed on the hole injection layer HIL. The hole transport layer HTL may be positioned between the hole injection layer HIL and the light-emitting layers EML1, EML2, and EML3. The hole transport layer HTL may be integrally formed across the sub-pixels PX1, PX2, and PX3. The hole transport layer HTL may be made of one or more materials selected from a group including aryloamine-based compounds such as NPB (N, N′-naphthyl-N, N′-phenyl benzidine), TPD (N, N′-bis-(3-methylphenyl)-N, N′-bis-(phenyl)-benzidine), PPD, TTBND, FFD, p-dmDPS, TAPC, starburst aromatic amines such as TCTA, PTDATA, TDAPB, TDBA, 4-a, TCTA, spiro and ladder-type materials such as Spiro-TPD, Spiro-mTTB, Spiro-2, NPD (N, N-dinaphthyl-N, N′-diphenyl benzidine), s-TAD, and MTDATA (4,4′,4′′-Tris(N-3-methylphenyl-N-phenyl-amino)-triphenylamine), but the embodiments of this specification are not limited thereto.

The light-emitting layers EML1, EML2, and EML3 may be disposed on the hole transport layer HTL. The first sub-pixel PX1 may have the first light-emitting layer EML1, the second sub-pixel PX2 may have the second light-emitting layer EML2, and the third sub-pixel PX3 may have the third light-emitting layer EML3.

The light-emitting layers EML1, EML2, and EML3 may differ in thickness. For example, the first light-emitting layer EML1 may have a thickness of 60 to 80 nm, the second light-emitting layer EML2 may have a thickness of 30 to 50 nm, and the third light-emitting layer EML3 may have a thickness of 10 to 30 nm, but the embodiments of this specification are not limited thereto.

The first light-emitting layer EML1, second light-emitting layer EML2, and third light-emitting layer EML3 may include materials capable of emitting light in the visible light range by respectively transporting holes and electrons and recombining the holes and electrons.

An electron blocking layer EBL may be disposed on each of the light-emitting layers EML1, EML2, and EML3. The electron blocking layer EBL may be integrally disposed across the sub-pixels PX1, PX2, and PX3.

An electron transport layer ETL may be disposed on the electron blocking layer EBL. The electron transport layer ETL may be integrally disposed across the sub-pixels PX1, PX2, and PX3. The electron transport layer ETL may be composed of anthracene derivatives and lithium quinolate (Liq), or may include materials selected from oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole), but the embodiments of this specification are not limited thereto.

A second electrode 153 may be disposed on the electron transport layer ETL.

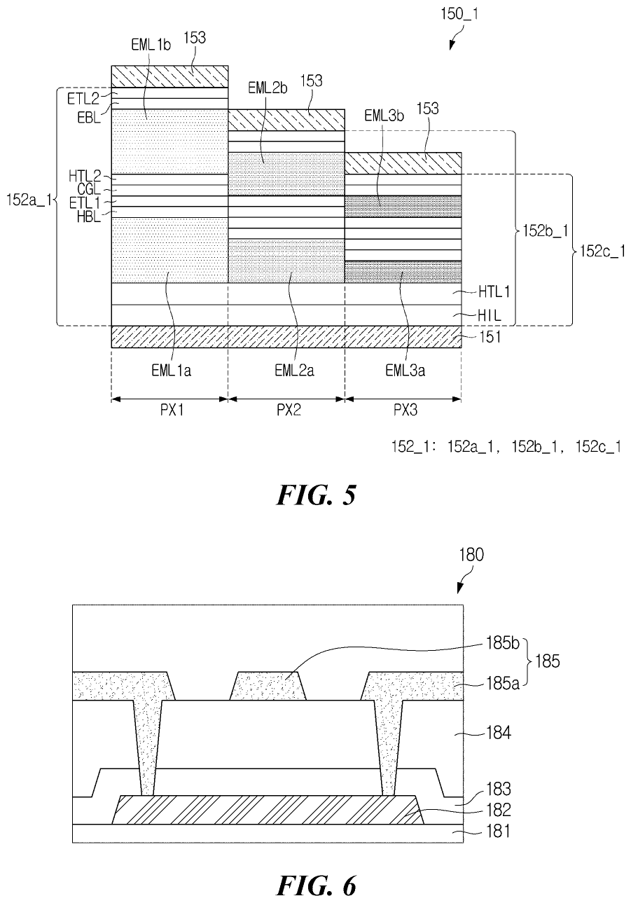

FIG. 5 is a detailed cross-sectional view of the light-emitting layer according to an alternative embodiment;

Referring to FIGS. 4 and 5, the organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

The light-emitting layers in respective organic layers 152a_1, 152b_1, and 152c_1 may be physically separated, but the lower and upper layers of the light-emitting layers may be integrally formed across the sub-pixels PX1, PX2, and PX3. The light-emitting layers may differ in thickness. For example, the first light-emitting layer in the first sub-pixel may have the greatest thickness, followed by the second light-emitting layer in the second sub-pixel, with the third light-emitting layer in the third sub-pixel having the smallest thickness, but the embodiments of this specification are not limited thereto. Additionally, the light-emitting layers in each organic layer 152a_1, 152b_1, and 152c_1 may include two or more layers.

The hole injection layer HIL may be disposed on the first electrode 151. The hole injection layer HIL may be positioned between the first electrode 151 and the light-emitting layers EML1a, EML2a, and EML3a. The hole injection layer HIL may be integrally formed across the sub-pixels PX1, PX2, and PX3. For example, the hole injection layer HIL may be made of a hole injection material selected from substances such as MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazole-3-yl)phenyl)-9H-fluorene-2-amine, but the embodiments of this specification are not limited thereto.

The first hole transport layer HTL1 may be disposed on the hole injection layer HIL. The first hole transport layer HTL1 may be positioned between the hole injection layer HIL and the light-emitting layers EML1a, EML2a, and EML3a. The first hole transport layer HTL1 may be integrally formed across the sub-pixels PX1, PX2, and PX3. The first hole transport layer HTL1 may be made of a material selected from a group including aryamine-based compounds such as NPB (N, N-naphthyl-N, N′-phenyl benzidine), TPD (N, N′-bis-(3-methylphenyl)-N, N′-bis-(phenyl)-benzidine), PPD, TTBND, FFD, p-dmDPS, TAPC, starburst aromatic amines such as TCTA, PTDATA, TDAPB, TDBA, 4-a, and TCTA, spiro and ladder type materials like Spiro-TPD, Spiro-mTTB, Spiro-2, as well as NPD (N, N-dinaphthyl-N, N′-diphenyl benzidine), s-TAD, and MTDATA (4,4′,4′′-Tris(N-3-methylphenyl-N-phenyl-amino)-triphenylamine), but the embodiments of this specification are not limited thereto.

The light-emitting layers EML1a, EML2a, and EML3a may be disposed on the first hole transport layer HTL1. The first sub-pixel PX1 may have a first-first emission layer EML1a disposed therein, the second sub-pixel PX2 may have a second-first emission layer EML2a disposed therein, and the third sub-pixel PX3 may have a third-first emission layer EML3a disposed therein. The light-emitting layers EML1a, EML2a, and EML3a may be identical to the respective light-emitting layers EML1, EML2, and EML3 in FIG. 4.

The light-emitting layers EML1a, EML2a, and EML3a may differ in thickness. For example, the first light-emitting layer EML1a may be formed with a thickness of 60 to 80 nm, the second light-emitting layer EML2a may be formed with a thickness of 30 to 50 nm, and the third light-emitting layer EML3a may be formed with a thickness of 10 to 30 nm, but the embodiments of this specification are not limited thereto.

A hole blocking layer HBL may be disposed on each of the light-emitting layers EML1a, EML2a, and EML3a. The hole blocking layer HBL may be integrally disposed across the sub-pixels PX1, PX2, and PX3.

A first electron transport layer ETL1 may be disposed on a hole blocking layer HBL. The first electron transport layer ETL1 may be integrally disposed across the sub-pixels PX1, PX2, and PX3. The first electron transport layer ETL1 may be made of a material selected from a group including anthracene derivatives and lithium quinolate (Liq), or oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of this specification are not limited thereto.

A common charge layer CGL may be disposed on the first electron transport layer ETL1. The common charge layer CGL may be disposed between the first electron transport layer ETL1 and the second hole transport layer HTL2. The common charge layer CGL may include a conductive material, but the embodiments of this specification are not limited thereto.

The second hole transport layer HTL2 may be disposed on the common charge layer CGL. The second hole transport layer HTL2 may be positioned between the hole blocking layer HBL and the light-emitting layers EML1b, EML2b, and EML3b. The second hole transport layer HTL2 may be integrally formed across the sub-pixels PX1, PX2, and PX3. The material of the second hole transport layer HTL2 may be the same as that of the first hole transport layer HTL1, but the embodiments of this specification are not limited thereto.

The light-emitting layers EML1b, EML2b, and EML3b may be disposed on the second hole transport layer HTL2. The first sub-pixel PX1 may have a first-second emission layer EML1b disposed therein, the second sub-pixel PX2 may have a second-second emission layer EML2b disposed therein, and the third sub-pixel PX3 may have a third-second emission layer EML3b disposed therein. The light-emitting layers EML1b, EML2b, and EML3b may be identical to the respective light-emitting layers EML1a, EML2a, and EML3a.

The light-emitting layers EML1b, EML2b, and EML3b may differ in thickness. For example, the first-second emission layer EML1b may be formed with a thickness of 600 to 800 Å, the second-second emission layer EML2b may be formed with a thickness of 300 to 500 Å, and the third-second emission layer EML3b may be formed with a thickness of 100 to 300 Å, but the embodiments of this specification are not limited thereto.

An electron blocking layer EBL may be disposed on each of the light-emitting layers EML1b, EML2b, and EML3b. The electron blocking layer EBL may be integrally disposed across the sub-pixels PX1, PX2, and PX3.

A second electron transport layer ETL2 may be disposed on an electron blocking layer EBL. The second electron transport layer ETL2 may be integrally disposed across sub-pixels PX1, PX2, and PX3. The second electron transport layer ETL2 may be made of an anthracene derivative and lithium quinolate Liq, or one or more selected from oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole), but the embodiments of this specification are not limited thereto.

A second electrode 153 may be disposed on the second electron transport layer ETL2.

Referring back to FIG. 3, a second electrode 153 may be disposed on the organic layer 152. The second electrode 153 may be a transparent electrode that allows light to pass through, but the embodiments of this specification are not limited thereto. For example, the second electrode 153 may include a transparent conductive material such as Indium Tin Oxide (ITO) or Indium Zinc Oxide (IZO), or a metal that allows visible light to pass through, but the embodiments of this specification are not limited thereto.

A bank 154 may be disposed to expose the first electrode 151. The bank 154 may define the openings (or emissive areas EA1, EA2, and EA3) of the sub-pixels PX1, PX2, and PX3 and may be disposed to cover the edge (or border, or peripheral) portion of the first electrode 151.

That is, the first sub-pixel PX1 may include the first emissive area EA1 and the first non-emissive area NEA1 surrounding the first emissive area EA1, the second sub-pixel PX2 may include the second emissive area EA2 and the second non-emissive area NEA2 surrounding the second emissive area EA2, and the third sub-pixel PX3 may include the third emissive area EA3 and the third non-emissive area NEA3 surrounding the third emissive area EA3. In other words, the non-emissive area NEA1, NEA2, and NEA3 may correspond to the boundaries between adjacent sub-pixels PX1, PX2, and PX3.

The bank 154 may include materials of the black series. For example, the bank 154 may be composed of a material containing black pigments, or organic materials such as benzocyclobutene resin, polyimide resin, acrylic resin, or photosensitive polymers, but the embodiments of this specification are not limited thereto. When the bank 154 is made of a material including a black pigment or a black dye, the bank 154 may be a black bank. When the bank 154 is made of a material including a black pigment or a black dye, the bank 154 may block light from the outside or block light reflected from the outside, thereby further improving the luminance of the display device.

A barrier RAS may be further disposed on the bank 154. As shown in FIG. 3, a barrier RAS may be disposed at all boundaries NEA1, NEA2, and NEA3 between sub-pixels PX1, PX2, and PX3, but the embodiments of this specification are not limited thereto. The barrier RAS may be directly disposed on an upper surface of the bank 154, but the embodiments of this specification are not limited thereto. The barrier RAS may serve to separate the organic layer 152 at the boundaries of adjacent sub-pixels PX1, PX2, and PX3. In some embodiments, a barrier may be omitted, and a trench may be formed in the bank 154. The trench may recess the bank 154 in a thickness direction.

A spacer 155 may be further disposed on the bank 154. The spacer 155 may be made of the same material as the bank 154, but the embodiments of this specification are not limited thereto. For example, the spacer 155 may be a transparent bank, but is not limited thereto and may also be made of the same material as the bank 154. For example, the spacer 155 may be disposed at the boundaries of at least one of the first to third sub-pixels PX1, PX2, and PX3, but the embodiments of this specification are not limited thereto. The bank 154 and spacer 155 may be made from the same material and may be formed simultaneously through a half-tone mask, but the embodiments of this specification are not limited thereto.

The organic layer 152 may be disposed on the first electrode 151, the bank 154, and the spacer 155. A second electrode 153 may be disposed on the organic layer 152.

An encapsulation layer 170 may be disposed on a second electrode 153. The encapsulation layer 170 may include one or more insulating layers. For example, the encapsulation layer 170 may include a first encapsulation layer 171, a second encapsulation layer 172 disposed on the first encapsulation layer 171, and a third encapsulation layer 173 disposed on the second encapsulation layer 172. The encapsulation layer 170 may include one or more inorganic insulating material layers and one or more organic material layers. For example, the first encapsulation layer 171 and the third encapsulation layer 173 may include inorganic insulating materials, while the second encapsulation layer 172 may include organic materials, but the embodiments of this specification are not limited thereto.

A touch layer 180 may be disposed on the encapsulation layer 170. The touch layer 180 may include a touch buffer layer 181, a first touch conductive layer, a first touch insulating layer 183, a second touch insulating layer 184, and a second touch conductive layer. In some embodiments, one or more touch organic layers may be further disposed on the second touch conductive layer, but the embodiments of this specification are not limited to this.

FIG. 6 is a cross-sectional view of the touch part according to FIG. 3.

Referring to FIGS. 3 and 6, a touch buffer layer 181 may be disposed on the encapsulation layer 170. For example, the touch buffer layer 181 may be disposed on the third encapsulation layer 173. The touch buffer layer 181 may be made of the same material as the buffer layer 102, but the embodiments of this specification are not limited thereto.

A first touch conductive layer may be disposed on the touch buffer layer 181. The first touch conductive layer may include a bridge electrode 182. The bridge electrode 182 and the sensor electrode 185, which will be described later, may be disposed at the boundaries between adjacent sub-pixels PX1, PX2, and PX3. For example, the bridge electrode 182 and the sensor electrode 185 may be disposed in the non-emissive areas NEA1, NEA2, and NEA3. The bridge electrode 182 and the sensor electrode 185 may overlap with the black matrix BM, which will be described later, in the thickness direction. The black matrix BM may cover the bridge electrode 182 and the sensor electrode 185. As a result, the bridge electrode 182 and the sensor electrode 185 may be prevented from being visible from the outside.

A first touch insulating layer 183 and a second touch insulating layer 184 disposed on the first touch insulating layer 183 may be disposed on a first touch conductive layer. The first touch insulating layer 183 and the second touch insulating layer 184 on top of the first touch insulating layer 183 may prevent a short circuit between the first touch conductive layer and the second touch conductive layer. The first touch insulating layer 183 may be formed of silicon oxide (SiOx), silicon nitride (SiNx), or a multilayer thereof, but the embodiments of this specification are not limited thereto. The second touch insulating layer 184 may include an organic insulating material; however, the embodiments of this specification are not limited thereto and may also include the same material as the first touch insulating layer 183.

A second touch conductive layer may be disposed on the second touch insulating layer 184. The second touch conductive layer may include a first sensor electrode 185a and a second sensor electrode 185b. The sensor electrodes 185 may include the first sensor electrode 185a extending in a first direction DR1 (see FIG. 1) and the second sensor electrode 185b extending in a second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrodes 185 and the bridge electrode 182 may include a metallic material. For example, they may be formed of titanium (Ti), nickel (Ni), aluminum (Al), or an alloy thereof and may be composed of three layers, such as titanium (Ti)/aluminum (Al)/titanium (Ti), but the embodiments of this specification are not limited thereto.

Referring back to FIG. 3, a filter insulating layer 114 may be disposed on the second touch conductive layer. The filter insulating layer 114 may be formed of an inorganic insulating material such as silicon nitride (SiNx) or silicon oxide (SiOx), but the embodiments of this specification are not limited thereto.

A black matrix BM may be disposed on the filter insulating layer 114. The black matrix BM may include a first black matrix BM1 and a second black matrix BM2 overlapping the first black matrix BM1.

The first black matrix BM1 may include a multilayer thin film structure. The second black matrix BM2 may include a black-colored material. For example, the black matrix (BM) may include a light-blocking material or a light-absorbing material. For example, the black matrix (BM) may be composed of a material containing black pigments or black dyes. The black matrix BM may cover the bridge electrode 182 and the sensor electrode 185. As a result, the bridge electrode 182 and the sensor electrode 185 may be prevented from being visible from the outside. For example, the width of the black matrix BM may be smaller than that of the bank 154.

For example, a separation distance between an end of a black matrix BM and a boundary between emission areas EA1, EA2, and EA3 and non-emission areas NEA1, NEA2, and NEA3 may be longer than a separation distance between an end of a bank 154 and a boundary between the emission areas EA1, EA2, and EA3 and the non-emission areas NEA1, NEA2, and NEA3. The edge of the bank 154 may be aligned with the boundary between the emissive areas (EA1, EA2, and EA3) and the non-emissive areas (NEA1, NEA2, and NEA3), but the embodiments of this specification are not limited thereto. In a case of a display panel 100 according to an embodiment, a bank 154 may include a black-based material, and a separation distance between an end of a black matrix BM and a boundary between emission areas EA1, EA2, and EA3 and non-emission areas NEA1, NEA2, and NEA3 being longer than a separation distance between an end of the bank 154 and a boundary between the emission areas EA1, EA2, and EA3 and the non-emission areas NEA1, NEA2, and NEA3, light emitted from the emission areas EA1, EA2, and EA3 may have a wider viewing angle by a space separated between the edge of the black matrix BM and the boundary between the emission areas EA1, EA2, and EA3 and the non-emission areas NEA1, NEA2, and NEA3, and may be emitted upward. As a result, the reduction in brightness due to the viewing angle can be improved. However, a separation distance between the edge of a black matrix BM and a boundary between emission areas EA1, EA2, and EA3 and non-emission areas NEA1, NEA2, and NEA3 being longer than a separation distance between the edge of a bank 154 and a boundary between the emission areas EA1, EA2, and EA3 and the non-emission areas NEA1, EA2, and NEA3, and the bank 154 being applied only with a transparent material, light incident from the outside may be reflected by the bank 154, causing a halo stain to be visible. However, in a case of a display panel 100 according to an embodiment, light incident from the outside being absorbed or blocked by the bank 154 containing a black-colored material, thereby improving the occurrence of halo stains.

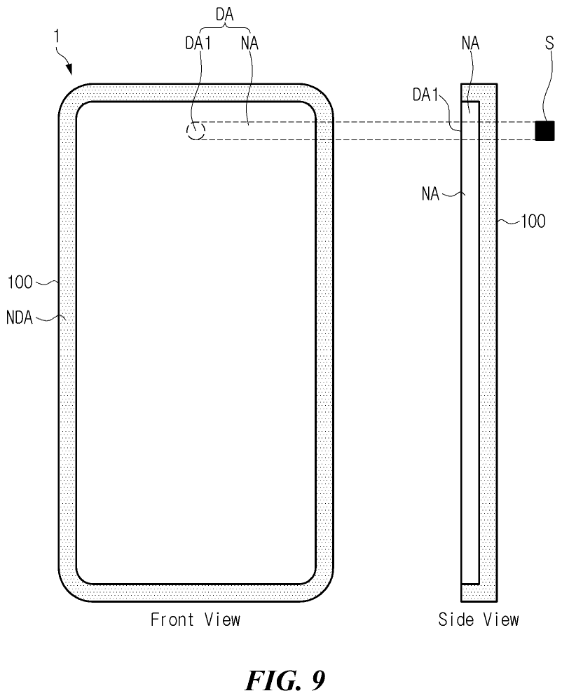

A description of a first black matrix BM1 and a second black matrix BM2 will be provided later in detail with reference to FIG. 9.

The color filters 191, 192, and 193 may be disposed on the black matrix BM. The color filters 191, 192, and 193 may be arranged in the first to third sub-pixels PX1, PX2, and PX3, respectively, to block specific colors from the light emitted from the emissive areas EA1, EA2, and EA3 of the respective sub-pixel PX1, PX2, and PX3. The first color filter 191 may be configured to block all colors except for red (R) light. In this case, the first color filter 191 may be a red color filter. The second color filter 192 may be configured to block all colors except for green (G) light. In this case, the second color filter 192 may be a green color filter. The third color filter 193 provided in the third sub-pixel PX3 may be configured to block all colors except for blue (B) light. In this case, the third color filter 193 may be a blue color filter. However, the embodiments of this specification are not limited thereto.

For example, the color filters 191, 192, and 193 may directly contact the sides and upper surfaces of the black matrix BM, respectively. For example, each color filter 191, 192, and 193 may be spaced from the boundary of adjacent sub-pixels PX1, PX2, and PX3, but the embodiments of this specification are not limited to this, and the filters may overlap in the thickness direction.

A planarization layer OC may be disposed on the color filters 191, 192, and 193. The planarization layer OC may serve to flatten the step formed by the color filters 191, 192, and 193. For example, the planarization layer OC may include an organic insulating material.

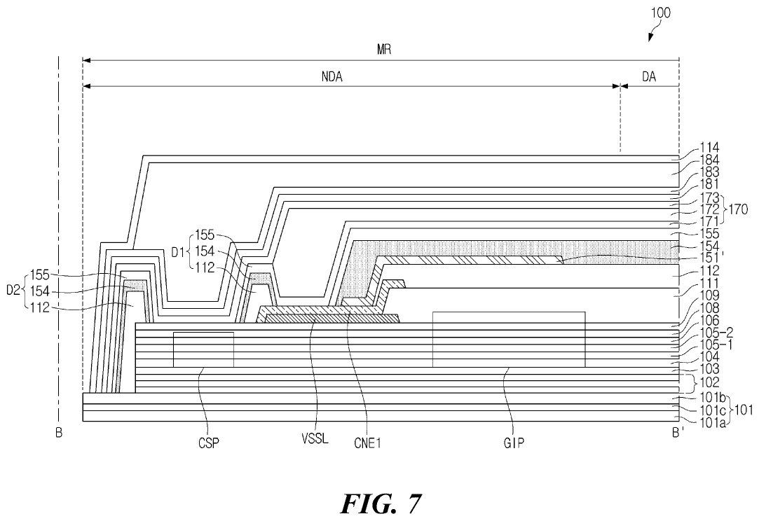

FIG. 7 is a cross-sectional view taken along line B-B′ of FIG. 1.

Referring to FIG. 7, at least one of the panel inorganic layers 102, 103, 104, 105-1, 105-2, 106, 108, and 109 may not extend to the edge of the substrate 101. That is, at least one of the panel inorganic layers 102, 103, 104, 105-1, 105-2, 106, 108, and 109 may expose the edge of the substrate 101, but the embodiments of this specification are not limited thereto.

In an embodiment, the display panel 100 may further include a crack detection pattern CSP, a low-potential voltage line VSSL, and a gate driving unit GIP. As described in FIG. 1, the low-potential voltage line VSSL may be located between the crack detection pattern CSP and the display area DA, and the gate driving unit GIP may be located between the low-potential voltage line VSSL and the display area DA.

For example, as shown in FIG. 7, a gate driver GIP may be made of a conductive layer located in a same layer as a first gate electrode 122 (see FIG. 3), a conductive layer located in a same layer as a second light-shielding layer 136 (see FIG. 3), or a conductive layer located in a same layer as a first source electrode 121, but the embodiments of this specification are not limited thereto.

For example, the crack detection pattern CSP may be arranged between the first dam D1 and the second dam D2. The crack detection pattern CSP may be composed of a conductive layer positioned in the same layer as the first gate electrode 122 (see FIG. 3) or a conductive layer positioned in the same layer as the second light-shielding layer 136 (see FIG. 3), but the embodiments of this specification are not limited thereto. For example, the crack detection pattern CSP may include a conductive layer positioned in the same layer as the first source electrode 121, but the embodiments of this specification are not limited thereto.

The low-potential voltage line VSSL may be arranged between the crack detection pattern CSP and the gate driving unit GIP. The low-potential voltage line VSSL may be composed of a conductive layer positioned in the same layer as the first source electrode 121, but the embodiments of this specification are not limited thereto.

The first protective layer 111 may cover the gate driving unit GIP, partially cover one end of the low-potential voltage line VSSL, and expose another portion of the low-potential voltage line VSSL. In this specification, one end refers to the area located in the direction towards the display area DA from a non-display area NDA, and the other end refers to the area located in the direction towards the non-display area NDA from a display area DA.

The first protective layer 111 may have the first connection electrode CNE1 arranged in the same layer as the connection electrode 145. The first connection electrode CNE1 may be directly connected to the area of the low-potential voltage line VSSL exposed by the first protective layer 111. The first connection electrode CNE1 may cover the other end of the low-potential voltage line VSSL, but the embodiments of this specification are not limited thereto.

The second protective layer 112 may be arranged on the first connection electrode CNE1. The second protective layer 112 may directly contact and cover one end of the first connection electrode CNE1, while exposing another portion of the first connection electrode CNE1. The second protective layer 112 may constitute the first layer of the first dam D1 and the first layer of the second dam D2. The second dam D2 may overlap with, for example, the low-potential voltage line VSSL and cover the other end of the low-potential voltage line VSSL. The second dam D2 may directly contact the first connection electrode CNE1 and cover the other end of the first connection electrode CNE2. The second protective layer 112, which forms the first layer of the first dam D1, may directly contact the exposed side surfaces of at least one of the panel inorganic layers 102, 103, 104, 105, 106, 107, and 109, and may directly contact the upper surface of the substrate 101, but the embodiments of this specification are not limited thereto. The second protective layer 112 may overlap with the gate driving unit GIP. Although the dam is illustrated as consisting of two parts in this specification, the dam may composed of three or more parts, or even just one part.

A first connection electrode CNE1 exposed by a second protective layer 112 and a low-potential connection electrode 151′ located in a same layer as a first electrode 151 (FIG. 3) may be disposed on the second protective layer 112. The low-potential connection electrode 151′ may be electrically connected to the first connection electrode CNE1 exposed by the second protective layer 112. A low-potential connection electrode 151′ may be electrically connected to a second electrode 153 (FIG. 3) described above in FIG. 3.

A bank 154 may be disposed on top of the low-potential connection electrode 151′ and the second protective layer 112. The bank 154 may overlap with the gate driving unit GIP and the low-potential connection electrode 151′, covering the other end of the low-potential connection electrode 151′. The bank 154 may fully cover the low-potential connection electrode 151′, but the embodiments of this specification are not limited thereto. The bank 154 may expose the center and the other end of the first connection electrode CNE1, but the embodiments of this specification are not limited thereto. The bank 154 may form the second layer of the first dam D1 and the second layer of the second dam D2. In each of the dam D1 and D2, the bank 154 may overlap with the second protective layer 112 forming the first layer and may completely cover the second protective layer 112, but the embodiments of this specification are not limited thereto. In the second dam D2, the bank 154 may contact the side of the second protective layer 112 and the upper surface of the substrate 101, but the embodiments of this specification are not limited thereto.

An spacer 155 may be disposed on bank 154. The spacer 155 may overlap with the gate driving unit GIP. The spacer 155 may form the third layer of the dams D1 and D2. The spacer 155 forming the third layer of each of the dams D1 and D2 may overlap with the bank 154 forming the second layer and may completely cover the bank 154, but the embodiments of this specification are not limited thereto. In the second dam D2, the spacer 155 may contact the side of the bank 154 and the upper surface of the substrate 101, but the embodiments of this specification are not limited thereto.

An encapsulation layer 170 may be disposed on the spacer 155. The first encapsulation layer 171 extends to the gate driving unit GIP, the low-potential voltage line VSSL, the first dam D1, and the second dam D2, and may cover the outer surface of the second dam D2. The second encapsulation layer 172 may terminate at the first dam D1. The second encapsulation layer 172 may overlap with the gate driving unit GIP and the low-potential voltage line VSSL. The third encapsulation layer 173 extends to the gate driving unit GIP, the low-potential voltage line VSSL, the first dam D1, and the second dam D2, and may directly contact the first encapsulation layer 171 on the first dam D1, the crack detection pattern CSP, and the second dam D2.

The touch buffer layer 181 and the first touch insulating layer 183 extend to the gate driving unit GIP, the low-potential voltage line VSSL, the first dam D1, and the second dam D2, and may cover the outer surface of the second dam D2. The second touch insulating layer 184 extends to the gate driving unit GIP, the low-potential voltage line VSSL, the first dam D1, and the crack detection pattern CSP, and may terminate on the second dam D2, but the embodiments of this specification are not limited thereto.

The filter insulating layer 184 extends to the gate driving unit GIP, the low-potential voltage line VSSL, the first dam D1, and the second dam D2, and may directly contact the outer surface of the second touch insulating layer 184, but the embodiments of this specification are not limited thereto.

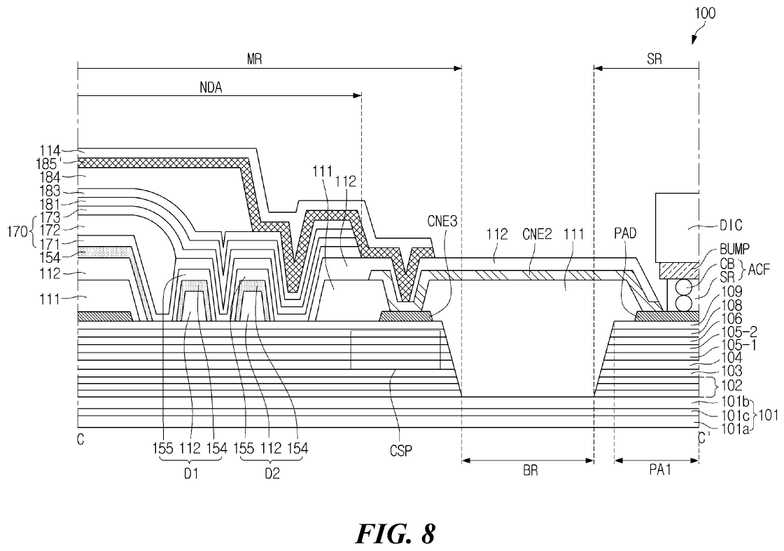

FIG. 8 is a cross-sectional view taken along line C-C′ of FIG. 1.

Referring to FIG. 3, FIG. 7, and FIG. 8, a bending region BR may be disposed between the sub-region SR and the crack detection pattern CSP. In the bending region BR, the panel inorganic layers 102, 103, 104, 105, 106, 107, and 109 may be removed, exposing the upper surface of the substrate 101.

In the first pad area PA1, a pad electrode PAD disposed in the same layer as the first source electrode 121 (see FIG. 3) is arranged, and a third connection electrode CNE3 disposed in the same layer as the first source electrode 121 (see FIG. 3) may be arranged on the crack detection pattern CSP.

A first protective layer 111 may be disposed on the pad electrode PAD and the third connection electrode CNE3. The first protective layer 111 is arranged in the bending region BR to directly contact the upper surface of the substrate 101 and the side surfaces of the panel inorganic layers 102, 103, 104, 105, 106, 107, and 109.

The second connection electrode CNE2 is arranged on the first protective layer 111, which may be positioned in the same layer as the connection electrode 145 (see FIG. 3). The second connection electrode CNE2 may electrically connect the pad electrode PAD and the third connection electrode CNE3. The second connection electrode CNE2 may be arranged across the bending region BR and the first pad area PA1 and above the crack detection pattern CSP.

The data driving unit DIC may be arranged on the pad electrode PAD. The data driving unit DIC includes bumps BUMP, and an anisotropic conductive film ACF is disposed between the pad electrode PAD and the bumps BUMP, electrically connecting the pad electrode PAD and the bumps BUMP. The anisotropic conductive film ACF may include a resin SR and a plurality of conductive balls CB dispersed in the resin SR. Through the conductive balls CB, the pad electrode PAD, and the bumps BUMP may be electrically connected.

A second protective layer 112 may be disposed on the second connection electrode CNE2. The second protective layer 112 may expose the pad electrode PAD.

The first and second encapsulation layers 171 and 173 of the encapsulation layer 170 may extend up to the bending region BR. For example, the first and second encapsulation layers 171 and 173 may extend up to the crack detection pattern CSP and may also overlap with the crack detection pattern CSP, but the embodiments of this specification are not limited thereto. The first and second encapsulation layers 171 and 173 may not be disposed in the bending region BR.

The touch buffer layer 181 and the first touch insulating layer 183 may extend up to the bending region BR. For example, the touch buffer layer 181 and the first touch insulating layer 183 may extend up to the crack detection pattern CSP and may also overlap with the crack detection pattern CSP, but the embodiments of this specification are not limited thereto. The touch buffer layer 181 and the first touch insulating layer 183 may not be disposed in the bending region BR.

The second touch insulating layer 184 may overlap with the first dam D1 and the second dam D2. The second touch insulating layer 184 may not be disposed on the outer side of the second dam D2, but the embodiments of this specification are not limited thereto.

The touch connection wiring 185′ may be electrically connected to the second connection electrode CNE2. The touch connection wiring 185′ may serve to provide the signal applied from the pad electrode PAD and the second connection electrode CNE2 to the first sensor electrode 185a or the second sensor electrode 185b, as described with reference to FIG. 3. The touch connection wiring 185′ may be located in the same layer as the second touch conductive layer (first sensor electrode 185a in FIG. 3) or may also be located in the same layer as the first touch conductive layer (bridge electrode 182 in FIG. 3) or consist of two layers of the first and second touch conductive layers, but the embodiments of this specification are not limited thereto.

The touch connection wiring 185′ may have a filter insulating layer 114 disposed thereon, and the filter insulating layer 114 may not be disposed in the bending region BR.

FIGS. 9 to 12 are schematic plan views of a display device according to an embodiment.

Referring to FIGS. 9 to 12, the display device 1 according to one embodiment of this specification may include a display panel 100 displaying an image and one or more optoelectronic devices S (or S1 and S2). The optoelectronic devices S, S1, and S2 may include a light-receiving device, such as a camera or a sensor.

The display panel 100 may include a display area DA and a non-display area NDA. The display area DA is an area of the display panel 100 where an image is displayed. The display area DA may include a plurality of sub-pixels constituting a plurality of pixels and a circuit for driving the plurality of sub-pixels.

Referring to FIGS. 9 to 12, the display area DA may include a first optical area DA1 and a second optical area DA2, but is not limited thereto.

In FIGS. 9 to 12, one or more optoelectronic devices S, S1, and S2 are electronic components located beneath the display panel 100 (on the opposite side of the viewing surface).

Light may enter the front of the display panel 100 (viewing surface), pass through the display panel 100, and be transmitted to one or more optoelectronic devices S, S1, and S2 located beneath the display panel 100 (on the opposite side of the viewing surface).

One or more optoelectronic devices S, S1, and S2 may receive light transmitted through the display panel 100 and perform a specified function based on the received light.

For example, the optoelectronic devices S, S1, and S2 may include at least one of a camera or a proximity sensor.

As mentioned above, the optoelectronic devices S, S1, and S2 are devices that require light reception but can be positioned beneath the display panel 100. That is, the optoelectronic devices S, S1, and S2 may be located on the opposite side of the viewing surface of the display panel 100. The optoelectronic devices S, S1, and S2 are not exposed on the front of the display device 1. Therefore, when a user looks at the front of the display device 1, the optoelectronic devices S, S1, and S2 are not visible.

As an example, a camera located beneath the display panel 100 may be a front-facing camera that captures images of the front and may be visible through the camera lens.

The optoelectronic devices S, S1, and S2 may be disposed to overlap with the display area DA of the display panel 100. That is, the optoelectronic devices S, S1, and S2 may be located within the display area DA.

Referring to FIGS. 9 to 12, the display area DA may include a general display area NA (also referred to as “a general area NA”) and one or more optical areas DA1 and DA2. One or more optical areas DA1 and DA2 may be regions that overlap with one or more optoelectronic devices S, S1, and S2.

According to the example of FIG. 9, the display area DA may include the general area NA and the first optical area DA1. Here, at least a part of the first optical area DA1 may overlap with the first optoelectronic device S. Although the first optical area DA1 is shown as circular in FIG. 9, the shape of the first optical area DA1 according to one embodiment is not limited to this.

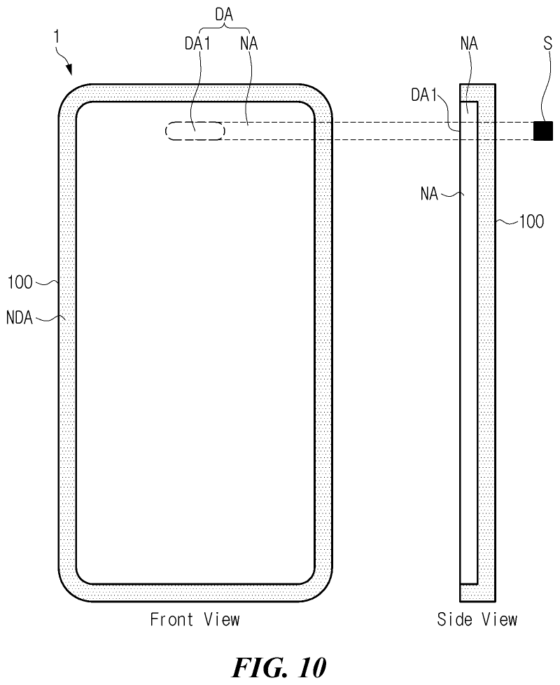

For example, as shown in FIG. 10, the shape of the first optical area DA1 may be octagonal, and it may also have other polygonal shapes.

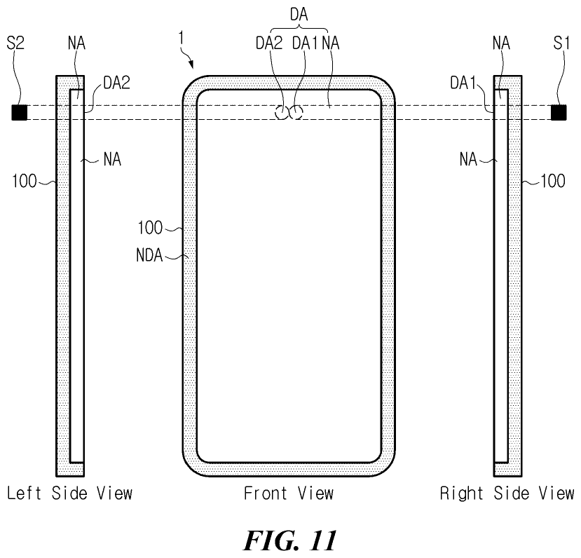

According to the example of FIG. 11, the display area DA may include a general area NA, the first optical area DA1, and the second optical area DA2. In the example of FIG. 11, the general area NA may exist between the first optical area DA1 and the second optical area DA2. Here, at least a part of the first optical area DA1 may overlap with the first optoelectronic device S1, and at least a part of the second optical area DA2 may overlap with the second optoelectronic device S2.

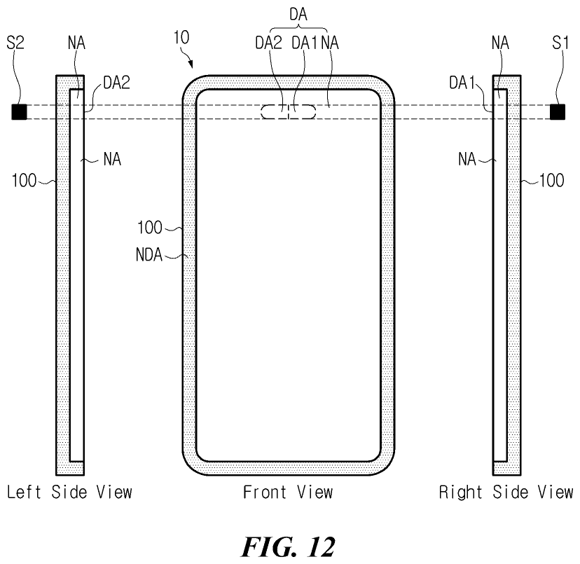

According to the example of FIG. 12, the display area DA may include a general area NA, the first optical area DA1, and the second optical area DA2. In the example of FIG. 12, there is no general area NA between the first optical area DA1 and the second optical area DA2. That is, the first optical area DA1 and the second optical area DA2 may contact each other. Here, at least a part of the first optical area DA1 may overlap with the first optoelectronic device S1, and at least a part of the second optical area DA2 may overlap with the second optoelectronic device S2.

One or more optical areas DA1 and DA2 must have both an image display structure and a light-transmissive structure formed. In other words, since one or more optical areas DA1 and DA2 are part of the display area DA, sub-pixels for image display must be arranged in one or more optical areas DA1 and DA2. One or more optical areas DA1 and DA2 must have a light-transmissive structure formed to transmit light for one or more optoelectronic devices S, S1 and S2.

One or more optoelectronic devices S, S1, and S2 are devices that require light reception, but they are located on the rear (bottom, opposite side of the viewing surface) of the display panel 100, receiving light that has passed through the display panel 100.

One or more optoelectronic devices S, S1, and S2 are not exposed on the front (viewing surface) of the display panel 100. Therefore, when the user looks at the front of the display device 1, the optoelectronic devices S, S1, and S2 are not visible to the user.

For example, the first optoelectronic device S (or S1) may be a camera, and the second optoelectronic device S2 may be a sensor, such as a proximity sensor or an illuminance sensor. For example, the sensor may be an infrared sensor that detects infrared light.

Conversely, the first optoelectronic device S (or S1) may be a sensor, and the second optoelectronic device S2 may be a camera.

For convenience of explanation, the first optoelectronic device S (S1) is taken as an example of a camera, and the second optoelectronic device S2 is taken as an example of a sensor. Here, the camera may be a camera lens or an image sensor.

When the first optoelectronic device S, S1 is a camera, this camera may be located on the rear (bottom) of the display panel 100 but may function as a front camera that captures the front direction of the display panel 100. Therefore, the user may capture images through a camera that is not visible on the viewing surface of the display panel 100 while looking at the viewing surface.

The general area NA and one or more optical areas DA1 and DA2, which are included in the display area DA, are regions where image display is possible, but the general area NA is a region where a light-transmissive structure does not need to be formed, and one or more optical areas DA1 and DA2 are regions where a light-transmissive structure must be formed.

Thus, one or more optical areas DA1 and DA2 must have a light-transmissive structure with a transmittance above a certain level, while the general area NA may either not have light transmissibility or may have a low transmittance below a certain level.

For example, one or more optical areas DA1 and DA2 and the general area NA may differ in terms of resolution, sub-pixel arrangement structure, number of sub-pixels per unit area, electrode structure, line structure, electrode arrangement structure, or line arrangement structure.

For example, the number of sub-pixels per unit area in one or more optical areas DA1 and DA2 may be smaller than the number of sub-pixels per unit area in the general area NA. That is, the resolution of one or more optical areas DA1 and DA2 may be lower than the resolution of the general area NA. In this case, the number of sub-pixels per unit area is a unit for measuring resolution, and may also be referred to as pixels per inch (PPI), which represents the number of pixels per inch.

For example, the number of sub-pixels per unit area in the first optical area DA1 may be smaller than the number of sub-pixels per unit area in the general area NA. The number of sub-pixels per unit area in the second optical area DA2 may be equal to or greater than that in the first optical area DA1.

The first optical area DA1 may have various shapes such as circular, elliptical, square, hexagonal, or octagonal. The second optical area DA2 may have various shapes such as circular, elliptical, square, hexagonal, or octagonal. The first optical area DA1 and the second optical area DA2 may have the same shape or different shapes.

Referring to FIG. 11, when the first optical area DA1 and the second optical area DA2 are in contact, the entire optical area, including the first optical area DA1 and the second optical area DA2, may also have various shapes such as circular, elliptical, square, hexagonal, or octagonal.

For convenience of explanation, it is assumed that the first optical area DA1 and the second optical area DA2 are each circular.

In the display device 1 according to an embodiment, when the first optoelectronic device S (or S1), which is hidden beneath the display panel 100 and not exposed to the outside, is an infrared sensor (or near-infrared sensor), the display device 1 according to this embodiment may be referred to as a display with UDIR technology applied.

Accordingly, in the display device 1 according to this embodiment, no notch or camera hole for exposing a camera to the display panel 100 needs to be formed, so there is no reduction in the area of the display area DA.

As a result, since no notch or camera hole for exposing a camera to the display panel 100 needs to be formed, the size of the bezel area can be reduced, and the design constraints are eliminated, leading to a greater degree of freedom in design.

In the display device 1 according to this embodiment, even though one or more optoelectronic devices S, S1, and S2 are hidden behind the display panel 100, they must be able to receive light normally and perform their intended functions properly.

Moreover, in the display device 1 according to this embodiment, even though one or more optoelectronic devices S, S1, and S2 are hidden behind the display panel 100 and overlap with the display area DA, normal image display must be possible in one or more optical areas DA1 and DA2 overlapping with the optoelectronic devices S, S1, and S2.

Therefore, the display device 1 according to an embodiment of this specification may have a structure that enhances the transmittance of the first optical area DA1 and second optical area DA2, which overlap with the light-receiving devices S, S1, and S2.

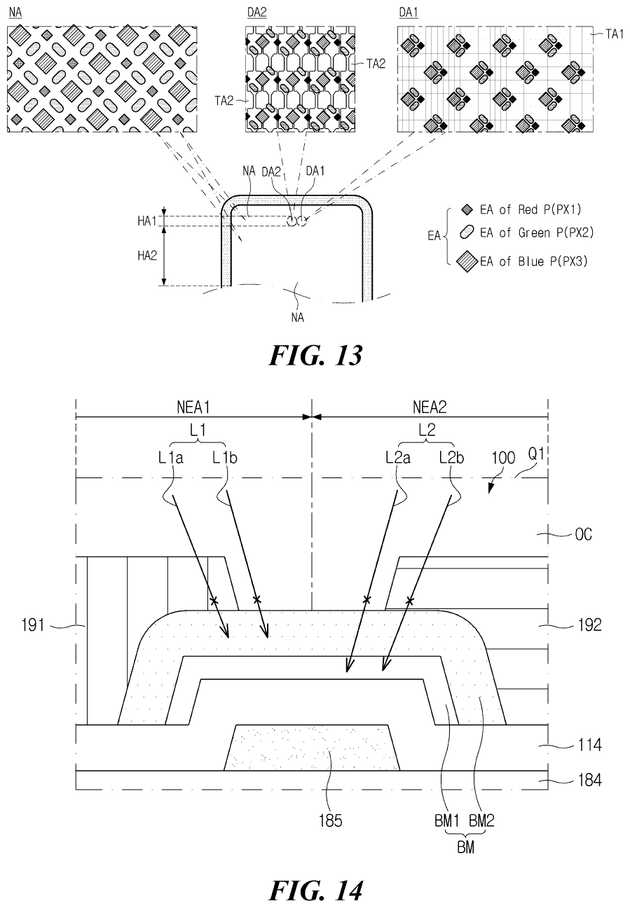

FIG. 13 is a diagram illustrating the arrangement of sub-pixels in the display area of a display panel according to an embodiment.

FIG. 13 shows the arrangement of sub-pixels in three areas NA, DA1, and DA2 included in the display area of the display panel according to an embodiment.

Referring to FIGS. 3 and 7, in the display area, the general area NA, first optical area DA1, and second optical area DA2 may each include a plurality of sub-pixels. The plurality of sub-pixels may include the first sub-pixel PX1, the second sub-pixel PX2, and the third sub-pixel PX3, as illustrated in FIG. 3.

As an example, the plurality of sub-pixels may include a red sub-pixel (Red SP) emitting red light (or the first sub-pixel PX1), a green sub-pixel (Green SP) emitting green light (or the second sub-pixel PX2), and a blue sub-pixel (Blue SP) emitting blue light (or the third sub-pixel PX3). In FIG. 13, the planar shape of the plurality of sub-pixels is exemplified as rectangular or elliptical; however, the embodiments of this specification are not limited to these, and the planar shape of the plurality of sub-pixels may also be circular.

Accordingly, each of the general area NA, first optical area DA1, and second optical area DA2 may include the emissive area (EA) of the red sub-pixel (Red SP) (refer to EA1 in FIG. 3), the emissive area (EA) of the green sub-pixel (Green SP) (refer to EA2 in FIG. 3), and the emissive area (EA) of the blue sub-pixel (Blue SP) (refer to EA3 in FIG. 3).

Referring to FIG. 13, the general area NA may include an emissive area EA without a light-transmissive structure. However, the first optical area DA1 and second optical area DA2 should not only include the emissive area EA but also a light-transmissive structure.

Thus, the first optical area DA1 may include the emissive area EA and the first transmissive area TA1, and the second optical area DA2 may include the emissive area EA and the second transmissive area TA2.

The emissive area EA and transmissive areas TA1 and TA2 may be distinguished based on their light transmissibility. That is, the emissive area EA may be a non-light-transmissive region, while the transmissive areas TA1 and TA2 may be light-transmissive regions.

Additionally, the emissive area EA and transmissive areas TA1 and TA2 may be distinguished based on the presence or absence of a specific metal layer. For example, a cathode electrode may be formed in the emissive area EA, while a cathode electrode may not be formed in the transmissive areas TA1 and TA2. Moreover, the emissive area EA may include a light-blocking layer, while the transmissive areas TA1 and TA2 may not include a light-blocking layer.

In this case, since the first optical area DA1 includes the first transmissive area TA1 and the second optical area DA2 includes the second transmissive area TA2, both the first optical area DA1 and the second optical area DA2 are regions where light can pass through.

At this time, the transmittance (degree of transmission) of the first optical area DA1 and the second optical area DA2 may be the same.

In this case, the first transmissive area TA1 in the first optical area DA1 and the second transmissive area TA2 in the second optical area DA2 may have the same shape or size. Alternatively, even through the shapes or sizes of the first transmissive area TA1 in the first optical area DA1 and the second transmissive area TA2 in the second optical area DA2 are different, the ratio of the first transmissive area TA1 in the first optical area DA1 to the second transmissive area TA2 in the second optical area DA2 may be the same. Alternatively, the transmittance (degree of transmission) of the first optical area DA1 and the transmittance (degree of transmission) of the second optical area DA2 may differ. In this case, the first transmissive area TA1 in the first optical area DA1 and the second transmissive area TA2 in the second optical area DA2 may have different shapes or sizes. Alternatively, even though the shapes or sizes of the first transmissive area TA1 in the first optical area DA1 and the second transmissive area TA2 in the second optical area DA2 are the same, the ratio of the first transmissive area TA1 in the first optical area DA1 to the second transmissive area TA2 in the second optical area DA2 may differ. For example, when the first optical area DA1 overlaps with the first optoelectronic device, which is a camera, and the second optical area DA2 overlaps with the second optoelectronic device, which is a detection sensor, the camera may require a larger amount of light than the detection sensor. Therefore, the transmittance (degree of transmission) of the first optical area DA1 may be higher than that of the second optical area DA2.

In this case, the first transmissive area TA1 in the first optical area DA1 may be larger than the second transmissive area TA2 in the second optical area DA2. Alternatively, even if the sizes of the first transmissive area TA1 in the first optical area DA1 and the second transmissive area TA2 in the second optical area DA2 are the same, the ratio of the first transmissive area TA1 in the first optical area DA1 may be larger than the ratio of the second transmissive area TA2 in the second optical area DA2.

Referring to FIG. 13, the horizontal display area in which the first optical area DA1 and the second optical area DA2 are arranged is referred to as the first horizontal display area HA1, and the horizontal display area in which the first optical area DA1 and the second optical area DA2 are not arranged is referred to as the second horizontal display area HA2.

Hereafter, the first black matrix BM1 and the second black matrix BM2 will be described in detail.

FIG. 14 is an enlarged cross-sectional view of Q1 area of FIG. 3. FIG. 14 illustrates only the cross-sectional structures of the first non-emissive area NEA1 of the first sub-pixel PX1 and the second non-emissive area NEA2 of the second sub-pixel PX2 in FIG. 3.

Referring to FIGS. 3 and 14, the first black matrix BM1 may include a multilayer thin-film structure, and the second black matrix BM2 may include a black-based material. The material of the second black matrix BM2 may be the same as the material of the bank 154 described above with reference to FIG. 3, though embodiments of this specification are not limited thereto.

The display device 1 (FIG. 1) according to an embodiment may not include a polarization layer. As a result, the flexibility of the display device 1 may be improved, allowing it to be applied to foldable products. However, since the polarization layer is omitted, the display device may be vulnerable to external light reflection (or surface reflection). To improve external light reflection, the black matrix BM or the bank 154 may include a black-based material. The black-based material may include an organic material and an inorganic material. When the black-based material includes an organic material (hereinafter referred to as organic BM), the organic BM may include a resin, a black-based dye or pigment dispersed in the resin, and an additive; and when the black-based material includes an inorganic material, the inorganic material may include carbon black.

Further, the display device 1 according to an embodiment (FIG. 9) may include an optoelectronic device S, S1, and S2 beneath the display panel 100. In particular, when at least one of the optoelectronic device S, S1, and S2 is an infrared sensor or a near-infrared sensor that detects infrared light or near-infrared light, near-infrared light must be transmitted from the optoelectronic device S, S1, and S2 toward a subject above the display panel 100, and near-infrared light reflected from the subject must pass through the display panel 100 to reach the optoelectronic device S, S1, and S2. Therefore, the display panel 100 must have high transmittance for near-infrared light while also improving external light reflection or surface reflection.

Hereinafter, the condition for improving external light reflection is referred to as the first condition, and the condition for achieving a high transmittance to near-infrared light is referred to as the second condition. The black matrix BM, BM1, BM2 must be designed to satisfy both the first and second conditions.

First, when the black-based material includes the aforementioned inorganic material, the transmittance to near-infrared light may be low (approximately 15.9%). Therefore, the black-based material of the inorganic material cannot be considered as the material for the black matrix BM, BM1, and BM2.

Accordingly, as the black matrix BM, BM1, and BM2, the organic black matrix BM may be considered, wherein the organic black matrix BM may have a higher transmittance to near-infrared light compared to the inorganic BM (approximately 88%). However, when only the organic BM is disposed in the black matrix BM (that is, when the first black matrix BM1 is omitted and only the second black matrix BM2 is disposed as illustrated in FIG. 14), absorption of light in a specific wavelength range may not be effectively achieved. To address this, increasing the content of the black-based material in the organic BM may be considered. Hereinafter, in relation to the content of the black-based material in the organic BM or the second black matrix BM2, the concept of optical density is introduced.

The absorption of external light by the second black matrix BM2 is related to optical density. The higher the optical density (hereinafter, referred to as OD), which is an indicator of how a material absorbs light, the greater the light absorption rate may be. Conversely, the lower the optical density (OD), the higher the light transmittance may be. For example, optical density (OD) is calculated based on a reference thickness of 1 μm and may be proportional to the thickness. Hereinafter, the optical density (OD) calculated with a reference thickness of 1 μm is referred to as “reference optical density (OD).”

Increasing the reference optical density (OD) of the second black matrix BM2 can improve the phenomenon where absorption of light in the aforementioned specific wavelength range is not effectively achieved. To increase the reference optical density (OD), increasing the content of the black-based material in the second black matrix BM2 may be considered.

However, increasing the content of the black-based material may lead to the volatilization of additives used to disperse the black-based materials in the second black matrix, which could degrade process reliability. Furthermore, increasing the reference optical density (OD) of the second black matrix may reduce the transmittance to near-infrared light of the second black matrix, which may degrade the light reception ability of the optoelectronic device S (FIG. 9).

Therefore, in the display panel according to one embodiment, in order to avoid increasing the reference optical density (OD) of the second black matrix, the first black matrix that overlaps with the second black matrix may be additionally disposed to compensate for the low absorption of light in specific wavelength ranges by the second black matrix. The first black matrix BM1 may include a multilayer thin film structure. The multilayer thin film structure includes a plurality of high refractive layers and low refractive layers, which may be alternately stacked.

The first black matrix BM1 has a high transmittance to near-infrared light (approximately 90% or more) while maintaining very low transmittance for red, green, and blue light. The transmittance of red, green, and blue light through the first black matrix BM1 may be lower than the transmittance of the second black matrix BM2.

As illustrated in FIG. 14, the second black matrix BM2 can absorb light L1a (e.g., red light) passing through the first color filter 191 and light L1b (e.g., red light, green light, or blue light) passing through the planarization layer OC. Although not shown in the drawing, the second black matrix BM2 may also absorb light (e.g., green light) passing through the second color filter 192.

As described above, light in a specific wavelength range not absorbed by the second black matrix BM2 can enter the first black matrix BM1 (see L2). That is, light L2b not absorbed by the second color filter 192 and the second black matrix BM2 (e.g., green light), and light L2a not absorbed by the second black matrix BM2 (e.g., red light, green light, or blue light) may enter the first black matrix BM1.

However, the first black matrix BM1 may absorb red light, green light, and blue light, excluding near-infrared light. As a result, the light passing through the second black matrix BM2 (light in wavelength ranges other than near-infrared light) can be absorbed to improve external light reflection (or surface reflection).

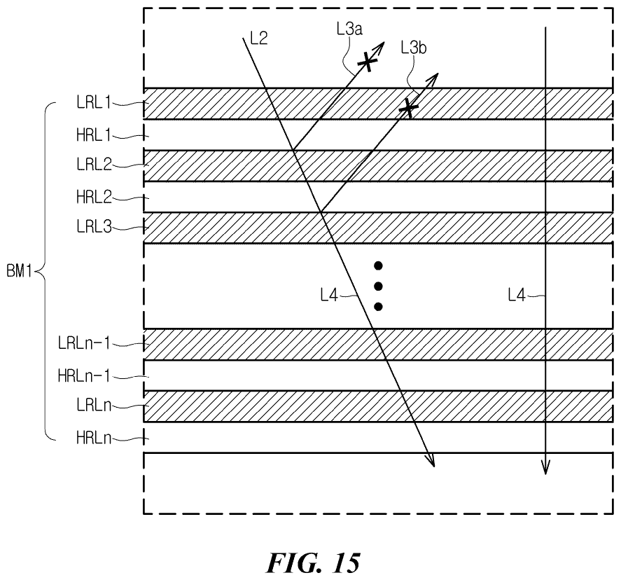

FIG. 15 is an enlarged cross-sectional view of the first black matrix of FIG. 14.

Referring to FIG. 15, the first black matrix BM1 may include a plurality of layers. The first black matrix BM1 may include a plurality of high refractive layers HRL1, HRL2, HRLn-1, and HRLn (where n is a natural number of 5 or greater) and a plurality of low refractive layers LRL1, LRL2, LRLn-1, and LRLn (where n is a natural number of 5 or greater). The plurality of high refractive layers HRL1, HRL2, HRLn-1, and HRLn and the plurality of low refractive layers LRL1, LRL2, LRLn-1, and LRLn may be alternately stacked in the thickness direction.

For example, the refractive index of the plurality of high refractive layers HRL1, HRL2, HRLn-1, and HRLn may range from approximately 3.0 to approximately 3.8, and the refractive index of the plurality of low refractive layers LRL1, LRL2, LRLn-1, and LRLn may range from approximately 1.5 to approximately 1.85.

To satisfy the refractive index range of the high refractive layers HRL1, HRL2, HRLn-1, and HRLn described above, the high refractive layers HRL1, HRL2, HRLn-1, and HRLn may include silicon hydride (Si—H), though embodiments of this specification are not limited thereto. For example, silicon hydride (Si—H) exhibits a high transmittance to light in a wavelength range from approximately 800 nm to approximately 1100 nm (the wavelength range of near-infrared light) compared to silicon (Si), and thus the high refractive layers HRL1, HRL2, HRLn-1, and HRLn according to an embodiment preferably include silicon hydride (Si—H).

Furthermore, the silicon hydride (Si—H) in the high refractive layers HRL1, HRL2, HRLn-1, and HRLn according to an embodiment may be amorphous silicon hydride (Si—H).

Amorphous silicon hydride (Si—H) may exhibit a higher transmittance to light in the wavelength range of near-infrared light compared to crystalline silicon hydride (Si—H). In addition, forming crystalline silicon hydride (Si—H) involves performing a crystallization process at a crystallization temperature after forming the light-emitting unit 150 of FIG. 3, and during this crystallization process, the organic layer 152 of FIG. 3 in the light-emitting unit 150 may be damaged. Therefore, the silicon hydride (Si—H) in the high refractive layers HRL1, HRL2, HRLn-1, and HRLn according to an embodiment may be amorphous silicon hydride (Si—H).

To satisfy the refractive index range of the low refractive layers LRL1, LRL2, LRLn-1, and LRLn described above, the low refractive layers LRL1, LRL2, LRLn-1, and LRLn may include silicon oxide or silicon oxynitride, though embodiments of the present specification are not limited thereto.

For example, the total number of the plurality of high refractive layers HRL1, HRL2, HRLn-1, and HRLn and the plurality of low refractive layers LRL1, LRL2, LRLn-1, and LRLn (that is, the number of layers in the first black matrix BM1) may range from approximately 10 to approximately 60. For example, the total number of the plurality of high refractive layers HRL1, HRL2, HRLn-1, and HRLn and the plurality of low refractive layers LRL1, LRL2, LRLn-1, and LRLn (that is, the number of layers in the first black matrix BM1) being less than approximately 10 may result in an increase in external light reflection or surface reflection in the first black matrix BM1. Furthermore, the total number of the plurality of high refractive layers HRL1, HRL2, HRLn-1, and HRLn and the plurality of low refractive layers LRL1, LRL2, LRLn-1, and LRLn (that is, the number of layers in the first black matrix BM1) exceeding approximately 60 may result in a decrease in the transmittance to near-infrared light.

Moreover, the total thickness of the high refractive layers HRL1, HRL2, HRLn-1, and HRLn may range from approximately 1500 nm to approximately 3500 nm, and the total thickness of the low refractive layers LRL1, LRL2, LRLn-1, and LRLn may range from approximately 150 nm to approximately 2000 nm. Generally, it is preferable for the total thickness of the high refractive layers HRL1, HRL2, HRLn-1, and HRLn to be greater than the total thickness of the low refractive layers LRL1, LRL2, LRLn-1, and LRLn. The reason the total thickness of the high refractive layers HRL1, HRL2, HRLn-1, and HRLn must be greater than the total thickness of the low refractive layers LRL1, LRL2, LRLn-1, and LRLn is that the low refractive layers LRL1, LRL2, LRLn-1, and LRLn may exhibit a higher transmittance to visible light (red light, green light, and blue light) compared to the high refractive layers HRL1, HRL2, HRLn-1, and HRLn. Therefore, it is preferable that the total thickness of the high refractive layers HRL1, HRL2, HRLn-1, and HRLn be greater than the total thickness of the low refractive layers LRL1, LRL2, LRLn-1, and LRLn.

In conclusion, the first black matrix BM1 according to an embodiment must satisfy the conditions including the refractive index range of the high refractive layers HRL1, HRL2, HRLn-1, and HRLn described above, the refractive index range of the low refractive layers LRL1, LRL2, LRLn-1, and LRLn, the material of the high refractive layers HRL1, HRL2, HRLn-1, and HRLn, the material of the low refractive layers LRL1, LRL2, LRLn-1, and LRLn, the total number of the plurality of high refractive layers HRL1, HRL2, HRLn-1, and HRLn and the plurality of low refractive layers LRL1, LRL2, LRLn-1, and LRLn, and the condition that the total thickness of the high refractive layers HRL1, HRL2, HRLn-1, and HRLn be greater than the total thickness of the low refractive layers LRL1, LRL2, LRLn-1, and LRLn.

In addition to the conditions described above, as previously mentioned, the first black matrix BM1 must absorb visible light (red light, green light, and blue light) while transmitting near-infrared light, and thus the refractive index range of the high refractive layers HRL1, HRL2, HRLn-1, and HRLn, the refractive index range of the low refractive layers LRL1, LRL2, LRLn-1, and LRLn, the thickness of each of the high refractive layers HRL1, HRL2, HRLn-1, and HRLn, and the thickness of each of the low refractive layers LRL1, LRL2, LRLn-1, and LRLn must be designed to satisfy the destructive interference condition for visible light.

For example, as described above with reference to FIG. 14, light in a specific wavelength range not absorbed by the second black matrix BM2 can enter the first black matrix BM1 (see L2). The second light L2 may include red light, green light, or blue light. As shown in FIG. 15, adjusting the thickness and refractive index of each of the first high refractive layer HRL1, the second low refractive layer LRL2, the second high refractive layer HRL2, and the third low refractive layer LRL3 can cause destructive interference of some of the red light, green light, or blue light within the second light L2 (see L3a, L3b). The plurality of high refractive layers HRL1, HRL2, HRLn-1, and HRLn and the plurality of low refractive layers LRL1, LRL2, LRLn-1, and LRLn according to an embodiment total between 10 and 60, and thus adjusting the thickness and refractive index of the sequentially stacked plurality of high refractive layers HRL1, HRL2, HRLn-1, and HRLn and plurality of low refractive layers LRL1, LRL2, LRLn-1, and LRLn can cause destructive interference of red light, green light, or blue light. However, the first black matrix BM1 must transmit near-infrared light L4, and therefore the thickness and refractive index conditions of the plurality of high refractive layers HRL1, HRL2, HRLn-1, and HRLn and the plurality of low refractive layers LRL1, LRL2, LRLn-1, and LRLn must be designed under conditions that do not cause destructive interference of near-infrared light L4.

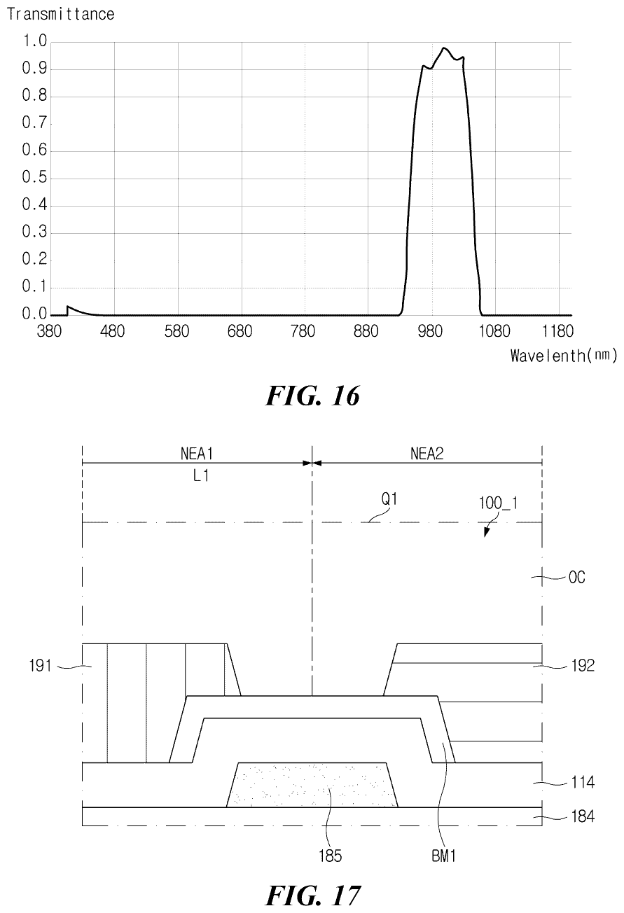

FIG. 16 is a graph illustrating the transmittance of near-infrared light with respect to wavelength in a black matrix according to an embodiment. FIG. 16 illustrates the transmittance of light as a function of wavelength for the first black matrix BM1 (FIG. 14). As illustrated in FIG. 16, the first black matrix BM1 of the display device according to an embodiment exhibits a very high transmittance to near-infrared light and a very low transmittance to visible light excluding near-infrared light, as can be confirmed.

Hereinafter, display devices according to other embodiments will be described. In the following embodiments, detailed explanations of the reference numerals or configurations already described with reference to FIGS. 1 to 16 will be omitted to avoid redundancy.

FIG. 17 is a cross-sectional view of a display device according to another embodiment.

Referring to FIG. 17, the display panel 100_1 of the display device according to this embodiment differs from the display panel 100 according to FIG. 14 in that the second black matrix BM2 (FIG. 14) is omitted.

More specifically, the first black matrix BM1 may directly contact the adjacent color filters 191 and 192 and may directly contact the planarization layer OC exposed by the color filters 191 and 192.

According to the display panel 100_1 of this embodiment, the absence of the second black matrix BM2 including an organic BM prevents the volatilization of additives or the like that may occur during the process of the organic BM. As a result, the process reliability can be enhanced.

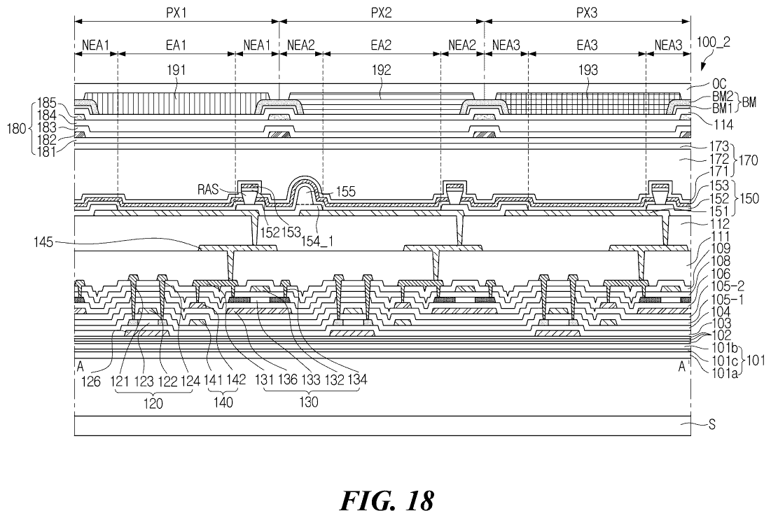

FIG. 18 is a cross-sectional view of a display device according to another embodiment.

Referring to FIG. 18, the display panel 100_2 of the display device according to this embodiment differs from the display panel 100 in FIG. 3 in that the bank 154_1 is formed with a multilayer thin film structure included in the first black matrix BM1 of FIG. 14.

According to this embodiment, the bank 154_1 may include a multilayer thin film structure. The multilayer thin film structure is as described above with reference to FIG. 14 and FIG. 15, and thus a detailed description thereof will be omitted. According to this embodiment, the bank 154_1 not including an organic BM (or black bank) and instead including a multilayer thin film structure increases the transmittance to near-infrared light of the display panel 100_2 and can improve the process reliability.

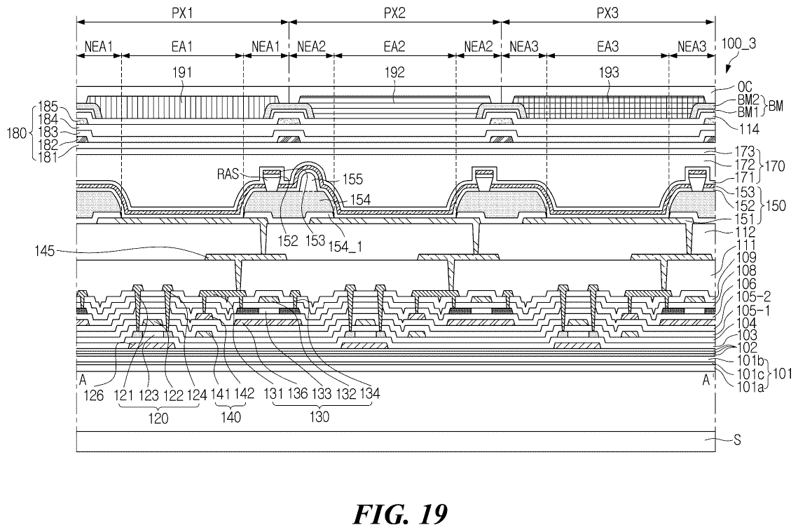

FIG. 19 is a cross-sectional view of a display device according to another embodiment.

Referring to FIG. 19, the display panel 100_3 of the display device according to this embodiment differs from the display panel 100 in FIG. 3 in that the bank 154_1 described above with reference to FIG. 18 is further disposed between the bank 154 and the first electrode 151.

According to this embodiment, the bank 154 being further disposed on the bank 154_1 provides the advantage that the optical density (OD) (or reference optical density) of the banks 154 and 154_1 can be further increased.

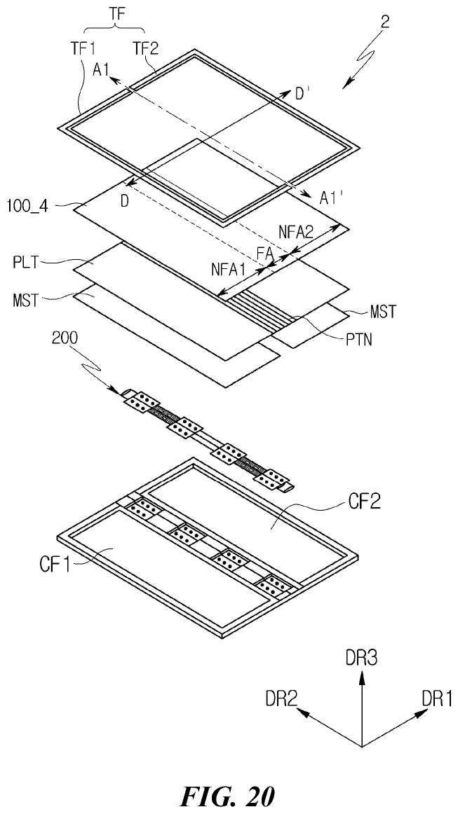

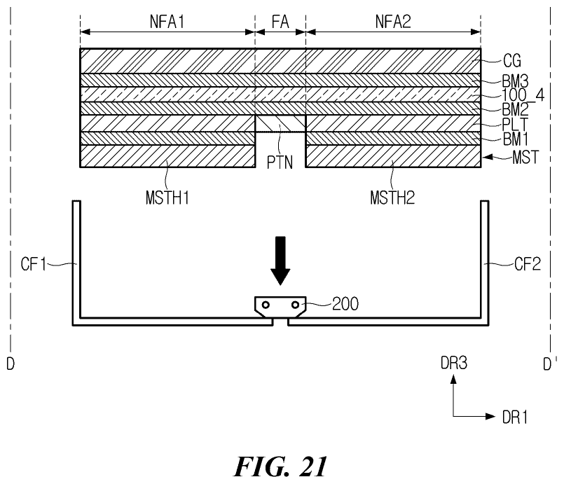

FIG. 20 is a perspective view of a display device according to another embodiment; and FIG. 21 is a cross-sectional view taken along line D-D′ of FIG. 20.

Referring to FIGS. 20 and 21, the display device 2 according to this embodiment differs from the display device 1 in FIG. 1 in that it is a foldable display device.

In this specification, the folding axis A1 around which the display device 2 folds may be the same as the second direction DR2.

A top frame TF is arranged at the topmost part of the display device 2. The top frame TF includes a first top frame TF1 arranged on one side and a second top frame TF2 arranged on the opposite side, with respect to the folding axis A1. The top frame TF is positioned to cover the edges of the display panel 100_3. The top frame TF may protect the display panel 100_3 from external impacts. The top frame TF may form the bezel of the display device 2.

A cover layer CG may be placed beneath the top frame TF. The cover layer CG is arranged on top of the display panel 100_4.

By being placed on top of the display panel 100_4, the cover layer CG serves to protect the components placed underneath from external forces.

The panel assembly is arranged on the underside of the cover layer CG. The panel assembly includes the display panel 100_3 and a plate PLT. The display panel 100_4 may be substantially the same as any of the display panels 100, 100_1, 100_2, or 100_3 described earlier.

The plate PLT may be placed beneath the display panel 100_4 and include various plates that support the display panel 100_4. For example, one or more plates may include a back plate that supports the display panel 100_4, a top plate formed of SUS material placed beneath the back plate, a bottom plate formed of SUS material with patterns formed at the folding section placed beneath the top plate, a heat dissipation sheet for heat dissipation, and a middle plate covering the non-planar surface due to the various components of the hinge assembly.

The plate PLT may have a slit pattern PTN formed thereon. The slit pattern PTN may be formed at the position corresponding to the folding area FA of the display panel 100_4. The slit pattern PTN may be an etched section in the shape of a slit formed in the plate PLT. The plate PLT may be made of metal, such as SUS material, which may cause the plate PLT to encounter resistance when folding or unfolding due to the metal's strength. The slit pattern PTN may provide flexibility to the plate PLT.

A middle plate MST is placed beneath the panel assembly. The middle plate MST supports the components arranged thereabove. Additionally, beneath the middle plate MST, the hinge assembly 200 and the cover frame CF are placed, upper surfaces of which may be uneven.

The middle plate MST may flatten the non-planar lower surface. The middle plate MST may be made of materials such as plastic, polyimide, or metal to enhance the rigidity of the display device 2. For example, the middle plate MST may include aluminum or SUS, but the embodiments of this specification are not limited to these materials.

The middle plate MST may include a first middle plate portion MSTH1 positioned in the first unfolding area NFA1 and a second middle plate portion MSTH2 positioned in the second unfolding area NFA2.

Below the panel assembly, the hinge assembly 200 is placed. The hinge assembly 200 is positioned at the lower part of the folding area FA. The hinge assembly 200 may have an elongated shape along the folding axis A1. The hinge assembly 200 may perform a folding motion with rotation on one side and the other side relative to the folding axis A1.

Beneath the hinge assembly 200, the cover frame CF is placed. A receiving groove may be formed on the upper surface of the cover frame CF, where a portion of the hinge assembly 200 may rest. The cover frame CF includes a first cover frame CF1 arranged on one side of the folding axis A1 and a second cover frame CF2 arranged on the opposite side. The cover frame CF may serve as a housing that defines the sides and rear of the display device 2. The cover frame CF can protect the display device 2 from external impacts. The cover frame CF can be coupled with the hinge assembly 200. Depending on the rotation of the cover frames CF1 and CF2, the folding and unfolding of the display device 2 may be implemented.

Additional coupling members AM1, AM2, and AM3 may be arranged between adjacent components MST, PLT, PNL, and CG to join the components together. The first coupling member AM1 may couple the middle plate portions MSTH1 and MSTH2 with the upper plate PLT in the respective unfolding areas NFA1 and NFA2, the second coupling member AM2 may couple the plate (PLT and PTN) with the upper display panel 100_4, and the third coupling member AM3 may couple the display panel 100_4 with the cover layer CG.

The coupled plate PLT and middle plate MST may be seated on the cover frames CF1 and CF2. The display device 2 may perform folding and unfolding actions through the hinge assembly 200 placed on the cover frames CF1 and CF2.

Detailed explanations regarding the display panel 100_4, as have already been made, will be omitted.

The display device according to various embodiments of this specification may be described as follows.

A display device according to the some embodiments of this specification includes a substrate 101 having a display area DA and a non-display area NDA adjacent to the display area DA. As shown in FIG. 3, the display area DA may include a plurality of sub-pixels PX1, PX2, PX3 arranged in a stripe, matrix, or pentile configuration. A first electrode 151 is disposed on the substrate 101. A bank 154 overlaps a peripheral region of the first electrode 151 in a plan view and is disposed on the upper surface of the first electrode 151. An organic layer 152 is disposed on the first electrode 151 and the bank 154, and a second electrode 153 is disposed on the organic layer 152. A black matrix BM is disposed on the second electrode 153 and overlaps the bank 154 in a plan view. In at least one embodiment, at least one of the bank 154 and the black matrix BM comprises a multilayer thin film structure including a plurality of first layers alternately stacked with a plurality of second layers, each first layer having a refractive index greater than the refractive index of each second layer.

As shown in FIG. 14-15, the multilayer thin film structure may be designed to reduce reflection of external light incident on the display panel 100 and to transmit near-infrared light while blocking visible light in at least one of the red, green, and blue wavelength ranges. The alternating first and second layers may have optical thicknesses selected to cause destructive interference in the visible wavelength band while maintaining high transmittance in the near-infrared band.

In some arrangements, and with reference to FIG. 3, a width of the black matrix BM between adjacent sub-pixels PX1, PX2 in a plan view is less than a corresponding width of the bank 154. This geometry can increase the effective viewing angle of emitted light while retaining light-blocking performance in non-emissive regions.

In some embodiments, the multilayer thin film structure is incorporated into the bank 154, and the black matrix BM comprises a resin material and is free of the multilayer thin film structure. The resin may be selected for light absorption, such as a pigment-containing polyimide or acrylic resin.

As further shown in FIG. 3, a spacer 155 may be disposed directly on the bank 154. The spacer 155 can be transparent or made of the same material as the bank and may be patterned concurrently with the bank using a half-tone mask.

In some cases, a barrier RAS is disposed adjacent to the spacer 155 and is positioned directly on the bank 154, as also illustrated in FIG. 3. The barrier may be configured to separate organic layers between adjacent sub-pixels.

In another embodiment, the multilayer thin film structure is disposed in the black matrix BM, and the bank 154 comprises a resin material free of the multilayer thin film structure. In yet another embodiment, both the bank 154 and the black matrix BM include the multilayer thin film structure.

In certain designs, the total thickness of all of the first layers in the multilayer thin film structure is greater than the total thickness of all of the second layers. This proportion may enhance interference-based reflection suppression while maintaining desired color filtering properties.

Referring to FIG. 1-2, the substrate 101 may include a main region MR, a sub-region SR, and a bending region BR between the main region and the sub-region. In one arrangement, the bending region BR has an exposed portion free of inorganic layers, thereby improving flexibility for folding.

As shown in FIG. 7, the bending region BR may include a dam structure disposed between the main region MR and the sub-region SR. The spacer 155 is disposed on the bank 154 in the display area. The dam structure may comprise a first dam layer formed on the substrate 101, a second dam layer of the same material as the bank 154, and a third dam layer formed of the spacer 155 material, the dam layers being stacked in that order.

In at least some embodiments, and referring again to FIG. 3, the bank 154 is disposed directly on the upper surface of the first electrode 151. This direct contact can improve adhesion and simplify fabrication.

Where the bank 154 comprises a resin free of the multilayer thin film structure, the resin may be a pigment-containing resin, such as a resin with dispersed black pigment or dye, as illustrated in FIG. 3.

The display device may further include a color filter 191, 192, 193 disposed on the second electrode 153 and the black matrix BM, and a touch unit 180 positioned between the second electrode and the color filter. The touch unit may comprise a bridge electrode 182 and a sensor electrode 185 disposed on the bridge electrode. The black matrix BM may have a width in plan view sufficient to completely cover the bridge electrode 182 and the sensor electrode 185, thereby concealing these electrodes from view when the display is observed from the front.

A display device according to additional embodiments of this specification includes a substrate including a display area having a plurality of sub-pixels and a non-display area surrounding the display area, a first electrode disposed on the substrate for each of the sub-pixels, a bank disposed on the first electrode and overlapping a peripheral edge of an upper surface of the first electrode, an organic layer on the first electrode and the bank, a second electrode on the organic layer, a black matrix disposed at a boundary between adjacent sub-pixels on the second electrode, and a color filter on the second electrode and the black matrix, wherein the bank or the black matrix are formed by alternating a plurality of high refractive index layers and a plurality of low refractive index layers.

The display device may further include an optoelectronic device disposed under the substrate and overlapping the display area.

In the display device according to the embodiments of this specification, the display area may include a general area and an optical area surrounding the general area, and the optoelectronic device overlaps the optical area.

In the display device according to the embodiments of this specification, a light transmittance of the general area may be lower than a light transmittance of the optical area.

In the display device according to the embodiments of this specification, the optoelectronic device may include an infrared sensor.

In the display device according to the embodiments of this specification, a refractive index of the high refractive index layers may range from 3.0 to 3.8, and a refractive index of the low refractive index layers may range from 1.5 to 1.85.

In the display device according to the embodiments of this specification, a total thickness of the plurality of high refractive index layers may be greater than a total thickness of the plurality of low refractive index layers.

In the display device according to the embodiments of this specification, the high refractive index layers may include silicon hydride, and the low refractive index layers may include silicon oxide or silicon oxynitride.

In the display device according to the embodiments of this specification, the multilayer thin film structure may include 10 to 60 layers.

In the display device according to the embodiments of this specification, the black matrix may include a first black matrix having the multilayer thin film structure and a second black matrix overlapping the first black matrix, and the second black matrix may include a black-based material.

In the display device according to the embodiments of this specification, the bank may include the multilayer thin film structure and a black bank overlapping the multilayer thin film structure.

In the display device according to the embodiments of this specification, the plurality of sub-pixels may include a first sub-pixel, a second sub-pixel, and a third sub-pixel, the organic layer may be disposed across the first sub-pixel, the second sub-pixel, and the third sub-pixel, the organic layer may include a first light-emitting layer on the first sub-pixel, a second light-emitting layer on the second sub-pixel, and a third light-emitting layer on the third sub-pixel.

In the display device according to the embodiments of this specification, the first light-emitting layer, the second light-emitting layer, and the third light-emitting layer may each be stacked in two or more layers in each sub-pixel.

In the display device according to various embodiments of this specification, a width of the black matrix may be smaller than a width of the bank.

In the display device according to the embodiments of this specification, an end of the black matrix may be closer to the boundary between adjacent sub-pixels than an end of the bank.

The display device, according to the embodiments of this specification, may further include a touch unit disposed between the second electrode and the color filter, wherein the touch unit may include a bridge electrode and a sensor electrode on the bridge electrode, and the black matrix may overlap the bridge electrode and the sensor electrode.

The embodiments of this specification are advantageous in providing a display device capable of enhancing applicability to foldable products by improving flexibility through the omission of a polarization layer.

The embodiments of this specification are advantageous in providing a display device capable of improving external light reflection (surface reflection) by adopting a black matrix or a bank composed of a plurality of high-refractive-index layers and a plurality of low-refractive-index layers alternately stacked.

The embodiments of this specification are advantageous in providing a display device incorporating a multilayer thin-film structure capable of transmitting near-infrared light while causing destructive interference of red, green, and blue light. As a result, even when an optoelectronic device for detecting near-infrared light is disposed below the display panel, the optoelectronic device may exhibit excellent near-infrared light reception capability.

The embodiments of this specification are advantageous in providing a display device capable of reducing surface reflection of external light and operating with low power consumption.

The advantages achievable through this specification are not limited to those mentioned above, and other advantages not explicitly described herein may be clearly understood by those skilled in the art from the following descriptions.

Although embodiments of this disclosure have been described above with reference to the accompanying drawings, it will be understood that the technical configuration of the this disclosure described above can be implemented in other specific forms by those skilled in the art without changing the technical concept or essential features of the present disclosure. Therefore, it should be understood that the embodiments described above are exemplary and not limited in all respects. Furthermore, the scope of the present disclosure is defined by the claims set forth below, rather than the detailed description above. In addition, it should be understood that all modifications or variations derived from the meaning and scope of the claims and their equivalent concept are included within the scope of the disclosure.

### DESCRIPTION OF REFERENCE NUMERALS

1: display device
100, 100_1, 100_2, 100_3, 100_4: display panel
D1, D2: dam

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area having a plurality of sub-pixels and a non-display area adjacent to the display area;
a first electrode on the substrate for each of the sub-pixels of the plurality, the first electrode having an upper surface;
a bank disposed on the first electrode and overlapping a periphery of the upper surface of the first electrode;
an organic layer on the first electrode and the bank;
a second electrode on the organic layer;
a black matrix at a boundary between adjacent sub-pixels of the plurality on the second electrode; and
a color filter on the second electrode and the black matrix,
wherein at least one of the bank and the black matrix comprises a multilayer thin film structure formed by alternating a plurality of high refractive index layers and a plurality of low refractive index layers.

2. The display device of claim 1, further comprising an optoelectronic device disposed under the substrate and overlapping the display area.

3. The display device of claim 2, wherein the display area comprises a general display area and an optical area surrounding the general display area, and the optoelectronic device overlaps the optical area in plan view.

4. The display device of claim 3, wherein a light transmittance of the general area is lower than a light transmittance of the optical area.

5. The display device of claim 2, wherein the optoelectronic device comprises an infrared sensor.

6. The display device of claim 1, wherein a refractive index of the high refractive index layers ranges from 3.0 to 3.8, and a refractive index of the low refractive index layers ranges from 1.5 to 1.85.

7. The display device of claim 1, wherein a total thickness of all of the plurality of high refractive index layers is greater than a total thickness of all of the plurality of low refractive index layers.

8. The display device of claim 1, wherein the high refractive index layers comprise silicon hydride, and the low refractive index layers comprise silicon oxide or silicon oxynitride.

9. The display device of claim 1, wherein the multilayer thin film structure comprises a total of 10 to 60 layers including both the plurality of high refractive index layers and the plurality of low refractive index layers.

10. The display device of claim 1, wherein the black matrix comprises a first black matrix having the multilayer thin film structure and a second black matrix overlapping the first black matrix, and the second black matrix comprises a black-based material.

11. The display device of claim 1, wherein the bank comprises the multilayer thin film structure and a black bank overlapping the multilayer thin film structure.

12. The display device of claim 1, wherein the plurality of sub-pixels comprise a first sub-pixel, a second sub-pixel, and a third sub-pixel, the organic layer is disposed across the first sub-pixel, the second sub-pixel, and the third sub-pixel, the organic layer comprises a first light-emitting layer on the first sub-pixel, a second light-emitting layer on the second sub-pixel, and a third light-emitting layer on the third sub-pixel, each light-emitting layer including two or more stacked layers.

13. The display device of claim 1, wherein a width of the black matrix is smaller than a width of the bank.

14. The display device of claim 13, wherein an end of the black matrix is closer to the boundary between adjacent sub-pixels than an end of the bank.

15. The display device of claim 1, further comprising a touch unit disposed between the second electrode and the color filter, wherein the touch unit comprises a bridge electrode and a sensor electrode on the bridge electrode, and the black matrix overlaps the bridge electrode and the sensor electrode in a plan view.

16. A display device comprising:
a substrate including a display area and a non-display area adjacent to the display area, the display area having a plurality of sub-pixels;
a first electrode on the substrate;
a bank overlapping a periphery of the first electrode in a plan view, the bank on the first electrode;
an organic layer on the first electrode and the bank;
a second electrode on the organic layer; and
a black matrix on the second electrode, the black matrix overlapping the bank in a plan view,
wherein at least one of the bank and the black matrix comprises a multilayer thin film structure, and
wherein the multilayer thin film structure includes a plurality of first layers alternately stacked with a plurality of second layers, each of the first layers having a refractive index greater than a refractive index of each of the second layers.

17. The display device of claim 16, wherein the multilayer thin film structure is configured to reduce reflection of external light and to transmit near-infrared light while blocking visible light in at least one of red, green, and blue wavelengths.

18. The display device of claim 16, wherein, in a plan view, a width of the black matrix between adjacent sub-pixels of the plurality is less than a corresponding width of the bank.

19. The display device of claim 16, wherein the multilayer thin film structure is disposed in the bank, and the black matrix comprises a resin and is free of the multilayer thin film structure.

20. The display device of claim 19, further comprising a spacer disposed directly on the bank.

21. The display device of claim 20, further comprising a barrier adjacent to the spacer, the barrier being disposed directly on the bank.

22. The display device of claim 16, wherein the multilayer thin film structure is disposed in the black matrix, and the bank comprises a resin free of the multilayer thin film structure.

23. The display device of claim 16, wherein the multilayer thin film structure is disposed in both the bank and the black matrix.

24. The display device of claim 16, wherein a total thickness of all of the first layers is greater than a total thickness of all of the second layers.

25. The display device of claim 16, wherein the substrate includes a main region, a sub-region, and a bending region between the main region and the sub-region, and
wherein the bending region of the substrate has an exposed portion free of inorganic layers.

26. The display device of claim 25, further comprising:
a dam structure in the bending region between the main region and the sub-region; and
a spacer on the bank,
wherein the dam structure in the bending region comprises a first dam layer on the substrate, a second dam layer of the same material as the bank, and a third dam layer of spacer material, the dam layers being stacked in the stated order.

27. The display device of claim 16, wherein the first electrode includes an upper surface, the bank disposed directly on the upper surface of the first electrode.

28. The display device of claim 22, wherein the resin is a pigment-containing resin.

29. The display device of claim 16, further comprising:
a color filter on the second electrode and the black matrix; and
a touch unit between the second electrode and the color filter,
wherein the touch unit comprises a bridge electrode and a sensor electrode on the bridge electrode,
wherein the black matrix has a width sufficient to completely cover the bridge electrode and the sensor electrode in a plan view.
